(19) United States
(12) Patent Application Publication
(10) Pub. No.: US 2026/0340236 A1
(43) Pub. Date: Oct. 29, 2026

(54) SYSTEMS AND METHODS FOR GENERATING CODE-COMPLIANCE CORRECTION PATHWAYS FROM AUTOMATED BUILDING-PLAN REVIEW FAILURES USING GENERATIVE ARTIFICIAL INTELLIGENCE

(71) Applicant: CodeComply.Ai, Corp., Miami, FL (US)

(72) Inventors: Patrick Hughes, Miami, FL (US); Patrick E. Murphy, Miami, FL (US)

(73) Assignee: CodeComply.Ai, Corp., Miami, FL (US)

(21) Appl. No.: 19/713,613

(22) Filed: Jun. 18, 2026

Related U.S. Application Data
(63) Continuation-in-part of application No. 18/999,973, filed on Dec. 23, 2024.
Application No. 18/999,973 is a continuation of application No. 18/508,722, filed on Nov. 14, 2023, now Pat. No. 12,197,829.
Application No. 18/508,722 is a continuation of application No. 18/211,187, filed on Jun. 16, 2023, now Pat. No. 12,462,080.
Application No. 18/211,187 is a continuation of application No. 17/809,585, filed on Jun. 29, 2022, now Pat. No. 11,714,940.
Application No. 17/809,585 is a continuation of application No. 17/697,691, filed on Mar. 17, 2022, now Pat. No. 11,797,733.
Application No. 17/697,691 is a continuation of application No. 17/515,774, filed on Nov. 1, 2021, now Pat. No. 11,475,174.
Application No. 18/508,722 is a continuation of application No. 18/049,142, filed on Oct. 24, 2022, now Pat. No. 12,437,246.
Application No. 18/049,142 is a continuation of application No. 17/591,868, filed on Feb. 3, 2022, now Pat. No. 11,481,704.
Application No. 17/591,868 is a continuation of application No. 17/515,774, filed on Nov. 1, 2021, now Pat. No. 11,475,174.
Application No. 18/508,722 is a continuation of application No. 17/967,047, filed on Oct. 17, 2022, now Pat. No. 12,124,772.
Application No. 17/967,047 is a continuation of application No. 17/515,774, filed on Nov. 1, 2021, now Pat. No. 11,475,174.
(63) Continuation-in-part of application No. 19/480,024, filed on Aug. 30, 2024.
(60) Provisional application No. 63/158,702, filed on Mar. 9, 2021.
(60) Provisional application No. 63/158,727, filed on Mar. 9, 2021.
(60) Provisional application No. 63/158,744, filed on Mar. 9, 2021.
(60) Provisional application No. 63/231,595, filed on Aug. 10, 2021.
(60) Provisional application No. 63/535,700, filed on Aug. 31, 2023.
(60) Provisional application No. 63/535,699, filed on Aug. 31, 2023.
(60) Provisional application No. 63/535,703, filed on Aug. 31, 2023.
(60) Provisional application No. 63/535,609, filed on Aug. 31, 2023.
(60) Provisional application No. 63/535,971, filed on Aug. 31, 2023.
(60) Provisional application No. 63/535,700, filed on Aug. 31, 2023.

(51) Int. Cl. G06F 30/27; G06F 30/13

(52) U.S. Cl. CPC G06F 30/27; G06F 30/13

(57) ABSTRACT

A system for analyzing a digital design plan of at least a portion of a building for compliance with a requirement adopted by, or enforced by an authority having jurisdiction. The system includes a controller and executable software. The controller receives the digital design plan, analyzes the digital design plan using an artificial intelligence engine to ascertain a design parameter, compares the design parameter against a requirement set, and detects a condition that does not comply with the requirement set. The controller constructs a failure context including data descriptive of the condition, plan geometry associated with the condition, and the implicated requirement. The failure context may be submitted to a generative language model, which returns a change to bring the digital design plan into compliance for presentation through the interactive user interface module.

### CROSS REFERENCE TO RELATED APPLICATIONS

The present application is a Continuation-in-Part of U.S. patent application Ser. No. 18/999,973, filed Dec. 23, 2024, and entitled APPARATUS FOR MANAGING SMOKE RELATED ASPECTS OF A BUILDING DESIGN PLAN (Attorney Docket CCAI0004CNT1), which is a continuation of U.S. patent application Ser. No. 18/508,722, filed Nov. 14, 2023, entitled ARTIFICIAL INTELLIGENCE DETERMINATION OF BUILDING SMOKE AND INDOOR AIR QUALITY MANAGEMENT, which claims the benefit of U.S. Provisional Patent Application Ser. Nos. 63/535,609, filed Aug. 31, 2023; 63/535,700, filed Aug. 31, 2023; 63/535,699, filed Aug. 31, 2023; 63/535,703, filed Aug. 31, 2023; and 63/535,971, filed Aug. 31, 2023; and U.S. patent application Ser. No. 18/508,722 is a continuation of and claims priority to U.S. patent application Ser. No. 18/211,187, filed Jun. 16, 2023, entitled APPARATUS FOR ARTIFICIAL INTELLIGENCE DETERMINATION OF BUILDING METRICS FOR CODE COMPLIANCE; which is a continuation of and claims priority to U.S. patent application Ser. No. 17/809,585, filed Jun. 29, 2022, entitled ARTIFICIAL INTELLIGENCE DETERMINATION OF BUILDING METRICS FOR CODE COMPLIANCE WITH USER INTERACTION; which is a continuation of and claims priority to U.S. patent application Ser. No. 17/697,691, filed Mar. 17, 2022, entitled ARTIFICIAL INTELLIGENCE DETERMINATION OF BUILDING METRICS FOR CODE COMPLIANCE; which is a continuation of and claims priority to U.S. patent application Ser. No. 17/515,774, filed Nov. 1, 2021, entitled METHODS AND APPARATUS FOR ARTIFICIAL INTELLIGENCE CONVERSION OF A TWO-DIMENSIONAL REFERENCE INTO AN ACTIONABLE INTERFACE; which claims the benefit of Provisional Patent Application Ser. No. 63/158,702, filed Mar. 9, 2021, entitled METHODS AND APPARATUS FOR PROCESSING TWO DIMENSIONAL DOCUMENTS WITH ARTIFICIAL INTELLIGENCE, Provisional Patent Application Ser. No. 63/158,727, filed Mar. 9, 2021, entitled METHODS AND APPARATUS FOR IMPROVED CONSTRUCTION ESTIMATION PROCESSES, and Provisional Patent Application Ser. No. 63/158,744, filed Mar. 9, 2021, entitled METHOD AND APPARATUS FOR GENERATING IMPROVED PROJECT MANAGEMENT; and U.S. patent application Ser. No. 18/508,722 also claims priority through continuations to U.S. patent application Ser. No. 18/049,142 , filed Oct. 24, 2022, U.S. patent application Ser. No. 17/591,868, filed Feb. 3, 2022, and U.S. patent application Ser. No. 17/967,047, filed Oct. 17, 2022. The present application is also a Continuation-in-Part of U.S. patent application Ser. No. 19/480,024 , filed Oct. 29, 2025, and entitled AUTOMATED WATER CLOSET COMPLIANCE ANALYSIS WITH INTERACTIVE USER FEEDBACK (Attorney Docket CCAI0001PCT-US), which is the National Phase of International Application Number PCT/US24/44858, filed Aug. 30, 2024, which claims the benefit of U.S. Provisional Application Ser. No. 63/535,700, filed Aug. 31, 2023, entitled ARTIFICIAL INTELLIGENCE DETERMINATION OF WATER CLOSET METRICS FOR CODE COMPLIANCE WITH USER INTERACTION. The entire disclosures of each of the applications identified above are incorporated herein by reference in their entirety.

### FIELD OF THE INVENTION

The present invention relates generally to systems, methods, and apparatus that employ artificial intelligence and generative language model techniques to analyze building design plans for regulatory compliance and, upon detecting one or more compliance failures, automatically generate a set of candidate remediation pathways that may resolve the identified failure conditions. More specifically, the invention provides a detection-to-remediation pipeline applicable across multiple building code frameworks that: identifies a specific failure condition within a design plan; constructs a failure context incorporating the relevant plan geometry and code requirement; submits that context to a generative AI model; receives and presents to the user a plurality of alternative correction options as design candidates for evaluation; verifies, upon user selection of a correction option, whether the selected modification resolves the original failure without introducing new violations through iterative compliance re-evaluation; and, in certain embodiments, autonomously regenerates or redraws the affected plan geometry to reflect the selected correction.

### BACKGROUND OF THE INVENTION

Building codes and regulatory standards govern the design, construction, and occupancy of buildings and structures throughout the United States and internationally. These codes include, by way of non-limiting example, the Americans with Disabilities Act Accessibility Guidelines (ADAAG), the American National Standards Institute (ANSI) standards, the International Building Code (IBC), the National Fire Protection Association (NFPA) codes including NFPA 101, the International Residential Code (IRC), the Uniform Plumbing Code (UPC), the National Electrical Code (NEC), and the International Plumbing Code (IPC), as well as a wide variety of state, regional, and local codes adopted and enforced by authorities having jurisdiction over specific geographic areas.

Compliance with these codes is required for design approval, construction authorization, and issuance of occupancy permits. Failure to achieve compliance before submission to an authority having jurisdiction results in plan rejection, revision cycles, project delays, and significant additional cost to the building owner, architect, and design team. The consequences of non-compliance discovered after construction include retrofitting expenses, legal liability, and in some cases loss of occupancy authorization.

Conventional methods for evaluating the compliance of a building design plan rely on manual review by experienced architects, engineers, and code inspectors. Such manual processes are time-intensive, prone to human error, and subject to inconsistent interpretation of code provisions among different reviewers. Even experienced professionals may overlook critical compliance requirements, particularly in complex buildings or in jurisdictions with layered regulatory frameworks. The growing complexity of building codes and the increasing number of applicable jurisdictions further compound these challenges.

Computer-aided design software and building information modeling platforms have introduced a degree of automation into the design workflow. However, these tools generally require skilled operators to manually configure compliance checks and do not provide automated, AI-driven analysis across the full range of applicable code requirements. They also do not, in general, generate actionable correction pathways when a violation is identified. Upon detecting a failure condition, prior art systems typically report the failure in the form of a pass-fail indicator or a static text description and require the architect or engineer to independently devise a corrective approach. This leaves the single largest burden of compliance work—determining how to resolve the failure—entirely on the human professional.

A specific and commercially significant gap exists in the art between the detection of a compliance failure and the generation of concrete, design-plan-grounded options for resolving that failure. What is needed is a system and method that, upon detecting a compliance failure in a building design plan, automatically analyzes the failure condition in the context of the specific plan geometry and applicable code requirement, generates a plurality of candidate correction pathways representing alternative design modifications that could resolve the failure, presents those candidates to the user as evaluation options rather than prescriptive directives, enables the user to select a candidate and verifies through automated iterative compliance re-evaluation whether the selected modification resolves the original failure without introducing new violations, and, in further embodiments, autonomously regenerates the affected plan geometry to reflect the selected or system-determined correction. The present invention addresses this gap.

### SUMMARY OF THE INVENTION

The present disclosure provides a system including a controller comprising one or more processors and a storage device, an artificial intelligence engine operative on the controller, a compliance rules database accessible to the controller, a generative language model accessible to the controller, and an interactive user interface module operative on the controller. The compliance rules database stores a requirement set associated with an authority having jurisdiction. The controller is configured to receive a digital design plan of at least a portion of a building, analyze the digital design plan using the artificial intelligence engine to ascertain at least one design parameter represented by the digital design plan, compare the at least one design parameter against the requirement set, and detect at least one condition of the digital design plan that does not comply with the requirement set. The controller is further configured to construct a failure context comprising data descriptive of the at least one condition, plan geometry associated with the at least one condition, and at least one requirement of the requirement set implicated by the at least one condition, submit the failure context to the generative language model, receive from the generative language model at least one candidate correction pathway describing a change to the digital design plan calculated to bring the digital design plan into compliance with the at least one requirement, and present the at least one candidate correction pathway through the interactive user interface module.

In some embodiments, the controller may select the requirement set based on a geographic location associated with the building. The artificial intelligence engine may identify architectural elements represented by the digital design plan and derive the at least one design parameter from the identified architectural elements. The failure context may further include a measured value for the at least one design parameter and a required value or threshold specified by the at least one requirement, and may further comprise data identifying a neighboring design element that constrains or affects the change described by the at least one candidate correction pathway. The controller may receive from the generative language model a plurality of candidate correction pathways that represent different alternative changes to the digital design plan, and the interactive user interface module may present the plurality of candidate correction pathways as candidate options subject to user evaluation and system verification rather than as certified compliant design solutions. The controller may receive a user selection of the at least one candidate correction pathway, apply the change described by the selected candidate correction pathway to a dynamic design plan representation, automatically re-run a compliance analysis on the dynamic design plan representation after application of the change, and determine whether the selected candidate correction pathway resolves the at least one condition without introducing a new condition that does not comply with the requirement set. The at least one candidate correction pathway may comprise geometric parameters directly applicable by the controller to modify a dynamic design plan representation.

The present disclosure further provides a system for fire code compliance analysis comprising a controller comprising one or more processors and a storage device, an artificial intelligence engine operative on the controller, a fire code rules database accessible to the controller, a generative language model accessible to the controller, and an interactive user interface module operative on the controller. The fire code rules database stores a fire code requirement adopted or enforced by an authority having jurisdiction. The controller is configured to receive a digital design plan of at least a portion of a building, analyze the digital design plan using the artificial intelligence engine to ascertain at least one fire-protection parameter represented by the digital design plan, compare the at least one fire-protection parameter against the fire code requirement, detect at least one condition of the digital design plan that does not comply with the fire code requirement, construct a failure context comprising data descriptive of the at least one condition, plan geometry associated with the at least one condition, and the fire code requirement implicated by the at least one condition, submit the failure context to the generative language model, receive from the generative language model at least one candidate correction pathway describing a change to the digital design plan calculated to bring the digital design plan into compliance with the fire code requirement, and present the at least one candidate correction pathway through the interactive user interface module. In some embodiments, the controller may select the fire code requirement based on a geographic location associated with the building, and the fire code requirement may comprise a requirement from a National Fire Protection Association code, an International Fire Code, an International Building Code, or a local fire code adopted by the authority having jurisdiction. The at least one fire-protection parameter may comprise an occupant load, an egress capacity, an egress width, a travel distance, a common path of travel, a dead-end corridor length, an exit separation distance, a door swing direction, a sprinkler spacing, a sprinkler coverage area, a sprinkler obstruction condition, a hazard classification, a detector spacing, a notification appliance coverage, a fire barrier continuity condition, a fire door rating, a smoke control parameter, a fire extinguisher travel distance, or a standpipe hose reach parameter. The failure context may include a measured value and a required value or threshold, and may comprise a dependency annotation identifying at least one additional fire-protection variable expected to be affected by the change described by the at least one candidate correction pathway. The controller may receive and present a plurality of candidate correction pathways as selectable options, apply a selected candidate correction pathway to a dynamic design plan representation, automatically re-run a fire code compliance analysis, and determine whether the selected candidate correction pathway resolves the at least one condition without introducing a new condition that does not comply with the fire code requirement.

The present invention provides systems, methods, and apparatus for generating code-compliance corrections from automated building-plan review failures using generative artificial intelligence. The invention takes as its point of departure a compliance failure condition identified by an AI-based compliance analysis system operating on a two-dimensional or other design plan representation, and transforms that failure condition into a plurality of candidate correction options that are grounded in the specific geometry of the plan and the specific requirements of the applicable code. In some embodiments, the present invention subjects one or more user-selected correction candidates to iterative compliance re-evaluation to confirm that the one or more user selected modification(s) resolves the original failure without introducing additional violations.

In one aspect, the present invention provides a computer-implemented method including: receiving into a controller a design plan of at least a portion of a building; analyzing the design plan using an artificial intelligence engine operative on the controller to detect one or more compliance failure conditions with respect to one or more applicable building code requirements; constructing, for each detected compliance failure condition, a failure context including data descriptive of the failure condition, the plan geometry associated with the failure condition, and the applicable code requirement or requirements; submitting the failure context to a generative language model; receiving from the generative language model a plurality of candidate correction pathways, each candidate correction pathway describing one or more modifications to the design plan that are calculated to resolve the failure condition; presenting the plurality of candidate correction pathways to a user via an interactive user interface as candidate options for evaluation and selection, the candidate options being presented without certification as compliant design solutions; receiving from the user a selection of one of the candidate correction pathways; applying the selected correction pathway to a representation of the design plan; and re-running the relevant compliance analysis on the modified design plan to verify that the selected correction resolves the original failure condition without introducing new compliance failure conditions.

In another aspect, the present invention provides a system including a controller including at least one processor and a storage device, and an artificial intelligence engine operative on the controller, wherein the controller is configured to: receive a digital design plan of at least a portion of a building; analyze the design plan using the AI engine to detect compliance failures against applicable building code requirements; for each detected compliance failure, construct a failure context and submit the failure context to a generative language model to generate a plurality of candidate correction pathways; present the candidate correction pathways via an interactive user interface; and re-evaluate compliance upon user selection of a correction pathway to verify resolution of the original failure condition and the absence of newly introduced violations.

In a further aspect, the generative language model employed by the present invention is not limited to any specific model architecture. In various embodiments, the generative language model may include a large language model, a transformer-based generative model, a fine-tuned domain-specific model trained on building code requirements and architectural design data, or any other generative AI model capable of receiving a structured failure context and producing natural-language or structured descriptions of candidate design modifications.

In still a further aspect, the invention includes embodiments in which the controller, following user selection of a correction pathway or upon autonomous determination of a preferred correction pathway, automatically redraws or regenerates the affected portion of the plan geometry to reflect the selected modification. In such embodiments, the generative AI model is not limited to suggesting textual correction options but may also output modified geometric parameters, fixture positions, dimension values, or other plan elements that are applied directly to the dynamic design plan representation maintained by the controller.

The present invention applies across essentially any compliance test or compliance code domain supported by an underlying compliance analysis engine. A correction pathway generation architecture is not limited to any specific building code, code type, or type of compliance failure. Examples of applicable code domains include, without limitation, ADA accessibility requirements, IBC egress, and occupancy requirements, NFPA fire and smoke control requirements, plumbing fixture count requirements, water closet accessibility requirements, wheelchair turning clearance requirements, structural requirements, electrical code requirements, and local and jurisdictional code requirements.

The present invention further provides that candidate correction pathways are presented to the user as design options for evaluation and are not presented as certified design solutions. This presentation modality reflects an important aspect of the invention: the generative AI model generates correction candidates based on analysis of the failure context and applicable code, but the verification of the ultimate compliance of any selected correction is performed by the iterative compliance re-evaluation component of the system rather than by assertion of compliance at the point of candidate presentation.

### BRIEF DESCRIPTION OF THE DRAWINGS

The accompanying drawings, which are incorporated herein and constitute a part of this specification, illustrate embodiments of the present invention and, together with the description, serve to explain aspects of the invention.

FIG. 1A illustrates method steps that may be implemented in some embodiments of the present invention for AI-based analysis of a building design plan, generation of an interactive user interface with dynamic components, and compliance determination.

FIG. 1B illustrates a high-level diagram of components included in a system that uses AI to generate an interactive user interface for building design plan compliance analysis.

FIG. 1C illustrates a design plan with multiple dwelling units and exemplary AI-analyzed egress paths.

FIG. 1D illustrates tables listing exemplary parameters that may be values for variables used in AI engine compliance analysis processes.

FIGS. 2A-2D illustrate a two-dimensional representation of a building design plan and AI analysis thereof to assess boundaries and regions.

FIGS. 3A-3D illustrate AI-analyzed boundaries overlaid on a building design plan including tables indicating hierarchical dominance relationships between area types.

FIGS. 4A-4B illustrate aspects of dominance-based area allocation in a building design plan analysis system.

FIGS. 5A-5D illustrate region identification and area allocation steps as may be performed by an AI engine analyzing a building design plan.

FIGS. 6A-6C illustrate boundary segmentation and classification steps as may be performed in some embodiments of the present invention.

FIG. 7 illustrates aspects of correction protocols as may be implemented in some embodiments of the present invention.

FIG. 8 illustrates exemplary controller and processor architecture for use with the present invention.

FIG. 9 illustrates exemplary mobile device architecture for use with the present invention.

FIGS. 10A-10B illustrate additional method steps for quantifying requirements for compliance analysis of a selected code applied to a building design plan.

FIG. 11 illustrates additional method steps for compliance analysis and iterative re-evaluation in some embodiments of the present invention.

FIGS. 12A-12D illustrate diagrams of paths of egress as analyzed by an AI engine in some embodiments.

FIG. 13 illustrates a path of egress with dead ends.

FIG. 14 illustrates determination of an egress path along a likely route.

FIGS. 15A-15B illustrate exemplary method steps for water closet compliance analysis as may be included in some embodiments of the present invention.

FIG. 16 illustrates an exemplary interactive user interface including compliance analysis results and visual compliance indication.

FIGS. 17A-17B illustrate exemplary allocation of space in a design plan for compliance analysis purposes.

FIG. 18 illustrates an exemplary interactive user interface including occupancy load compliance analysis.

FIG. 19 illustrates an exemplary interactive user interface including travel distance compliance analysis.

FIG. 20 illustrates an exemplary interactive user interface including common path compliance analysis.

FIG. 21 illustrates an exemplary interactive user interface including exit separation compliance analysis.

FIG. 22 illustrates a block diagram of exemplary aspects used in building or refining design models for AI analysis.

FIGS. 23A-23B illustrate exemplary method steps for multi-code compliance analysis in some embodiments.

FIG. 24 illustrates additional method steps for compliance analysis across building types.

FIG. 25 illustrates a multi-story residential building analyzed using methods described herein.

FIG. 26 illustrates a multi-story building and stairwell analyzed using the methods and apparatus described herein.

FIG. 27 illustrates multiple two-dimensional representations of a building analyzed using the present invention.

FIG. 28 illustrates vertical openings within a multi-story building requiring smoke control compliance analysis.

FIG. 29 illustrates dynamics of vertical openings relevant to occupant evacuation analysis.

FIG. 30 illustrates a high-level flow diagram of the detection-to-remediation pipeline of the present invention, showing the stages of failure detection, failure context construction, generative model querying, candidate option presentation, user selection, and iterative compliance re-evaluation.

FIG. 31 illustrates an exemplary interactive user interface showing a compliance failure condition flagged on a design plan, with a candidate correction pathway panel displaying multiple alternative correction options generated by the generative language model.

FIG. 32 illustrates the iterative verification loop of the present invention, showing a design plan representation before and after application of a user-selected correction pathway, and the results of automated compliance re-evaluation confirming resolution of the original failure condition.

FIG. 33 illustrates exemplary embodiments of the autonomous plan geometry regeneration capability of the present invention, showing the AI engine modifying and regenerating plan elements to reflect the selected correction pathway.

FIG. 34 illustrates a block diagram of system modules included in some embodiments of the present invention, including a controller, an AI engine, a generative language model, a compliance rules database, a failure context construction module, a correction pathway generation module, a dynamic design plan representation module, an interactive user interface module, and an iterative re-evaluation module.

FIG. 35 illustrates construction of a failure context in some embodiments of the present invention, showing data elements aggregated into the failure context and submission of the failure context to a generative language model to produce candidate correction pathways.

FIG. 36 illustrates a dependency cascade among interdependent fire protection compliance variables and an iterative re-verification sweep performed upon application of a selected correction pathway in some embodiments of the present invention.

FIG. 37 illustrates sprinkler coverage and obstruction analysis of a design plan, candidate correction pathways generated for a sprinkler coverage failure, and an inset illustrating a portable fire extinguisher travel distance coverage map, in some embodiments of the present invention.

FIG. 38 illustrates presentation of candidate correction pathways including a threshold-shifting alternative compliance candidate with a dependency annotation, together with an inset illustrating an exit remoteness separation analysis, in some embodiments of the present invention.

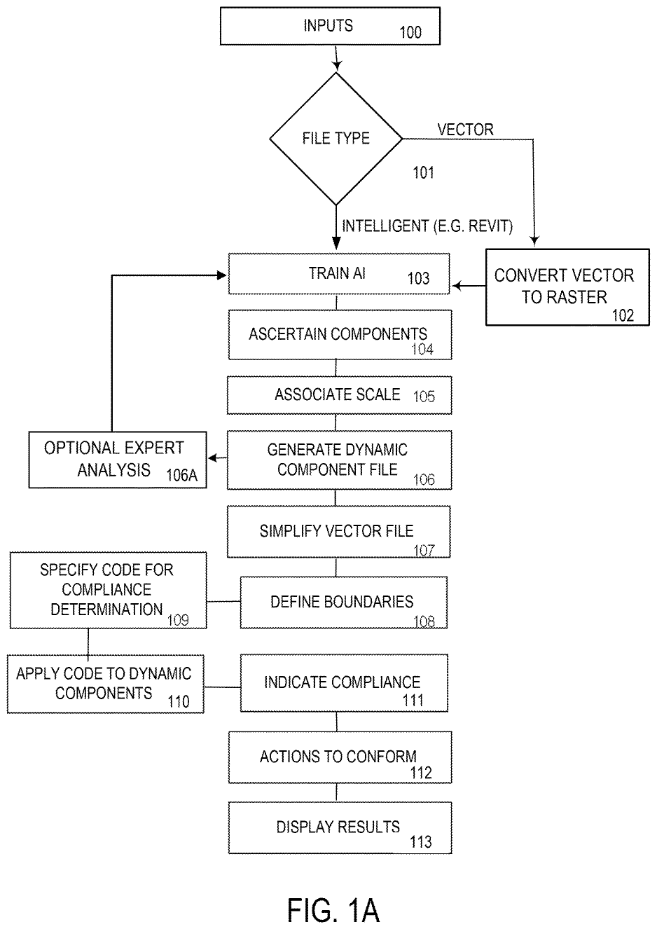

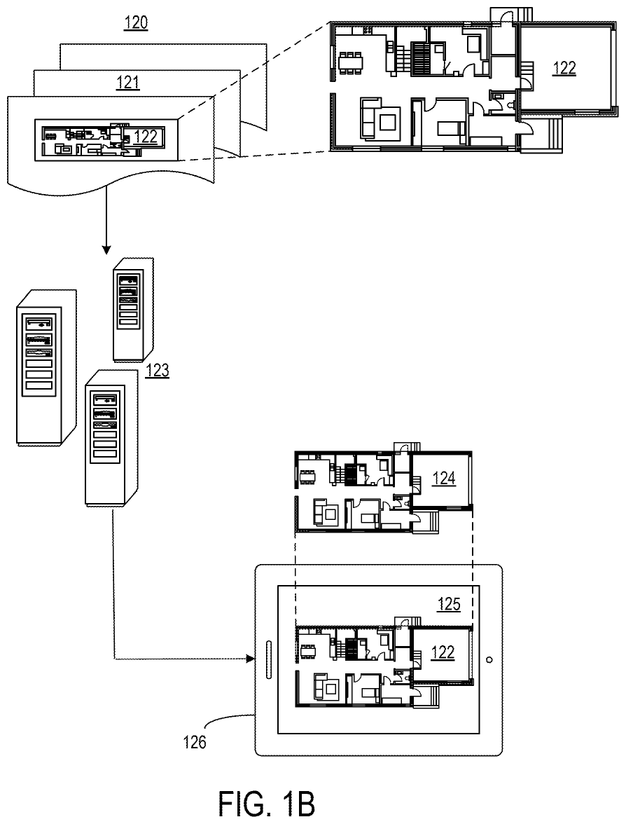

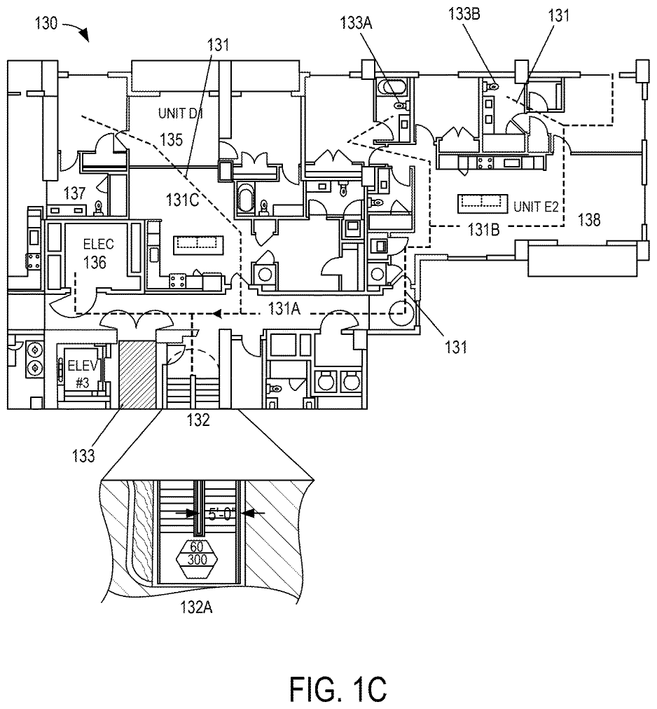

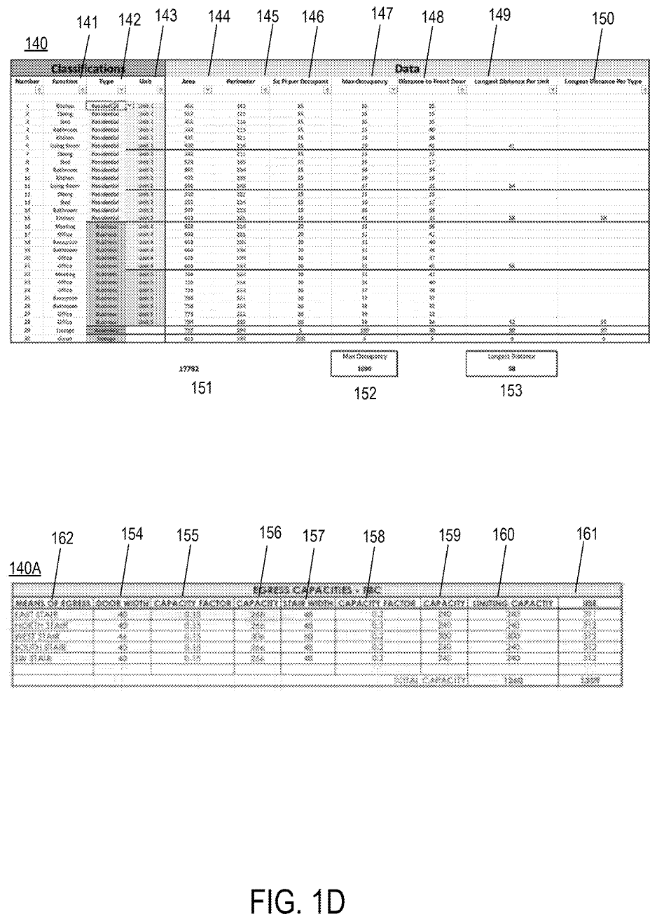

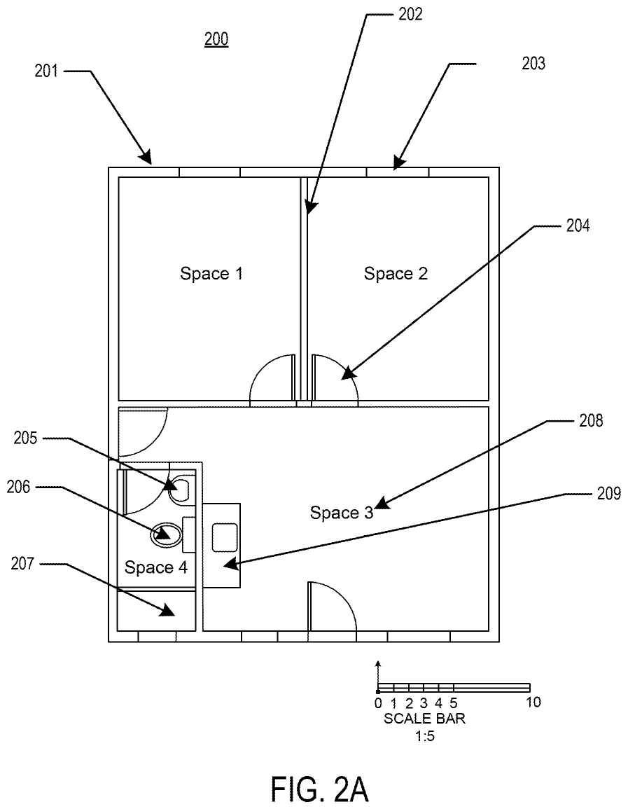

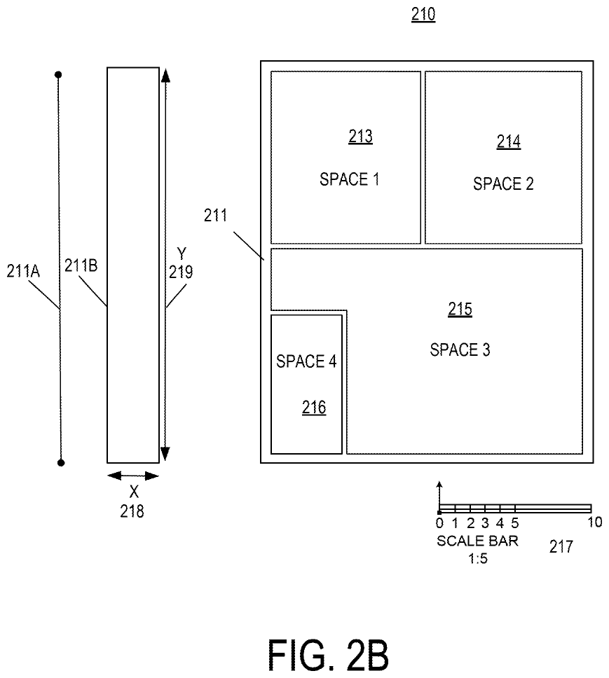

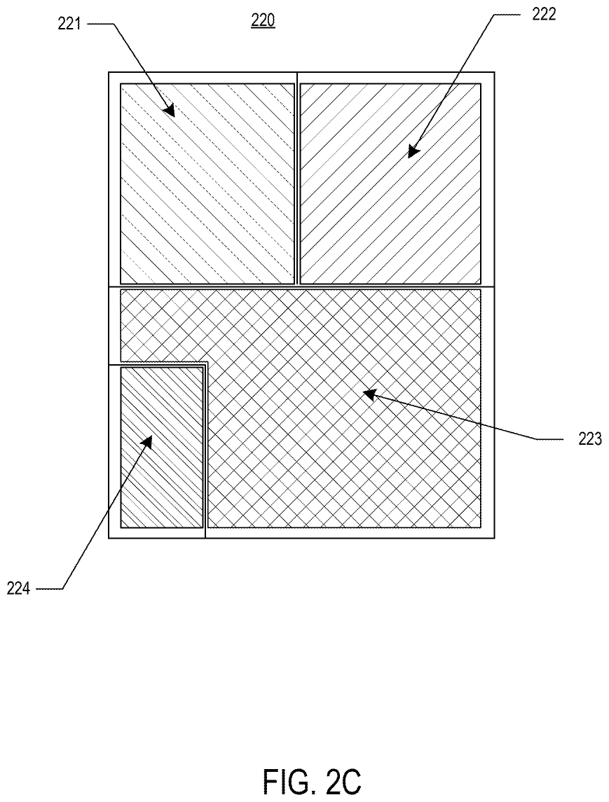

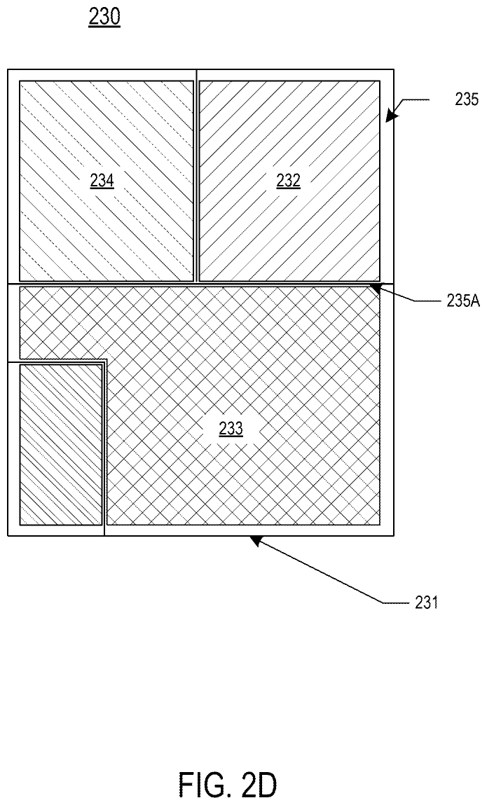

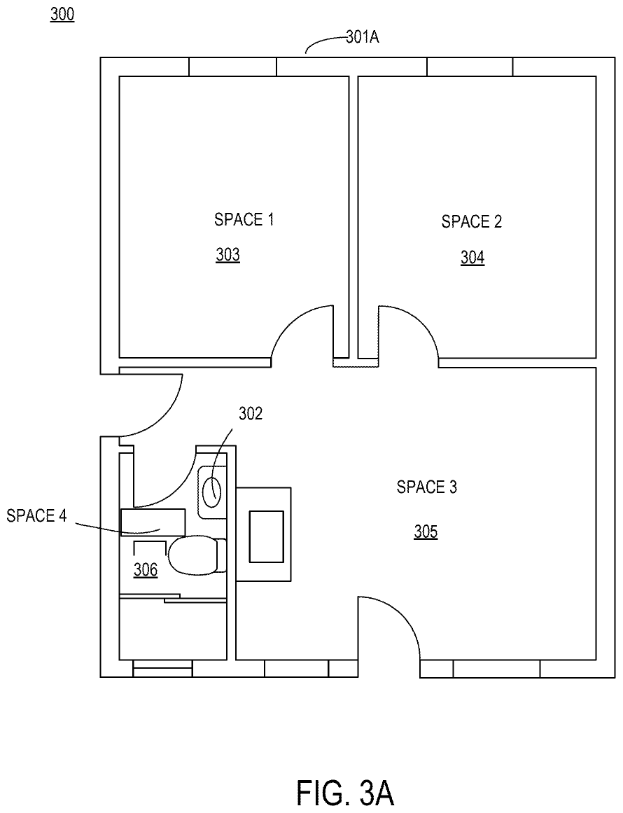

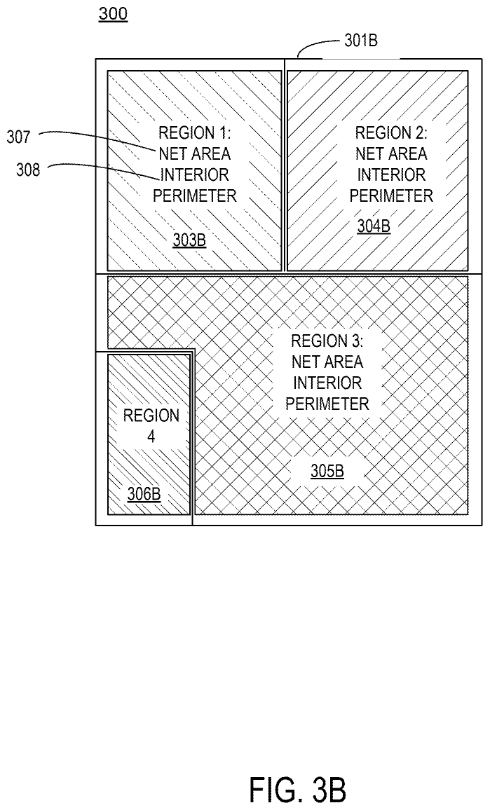

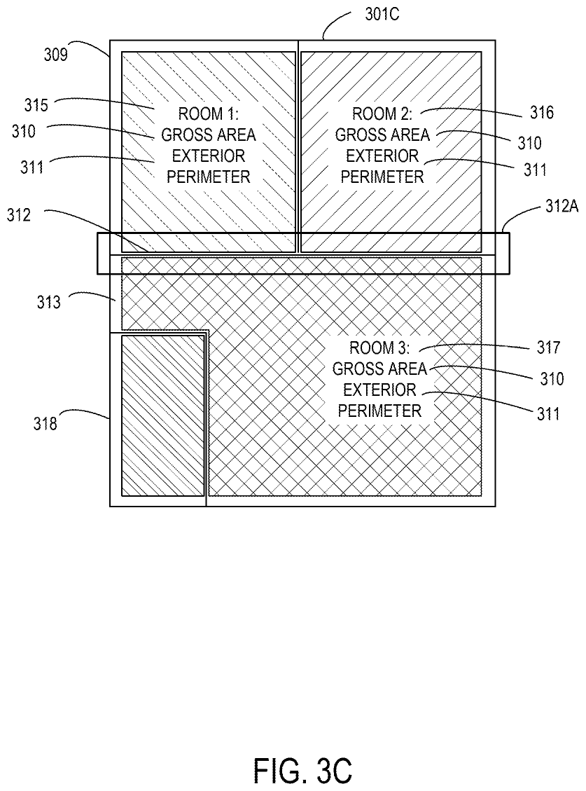

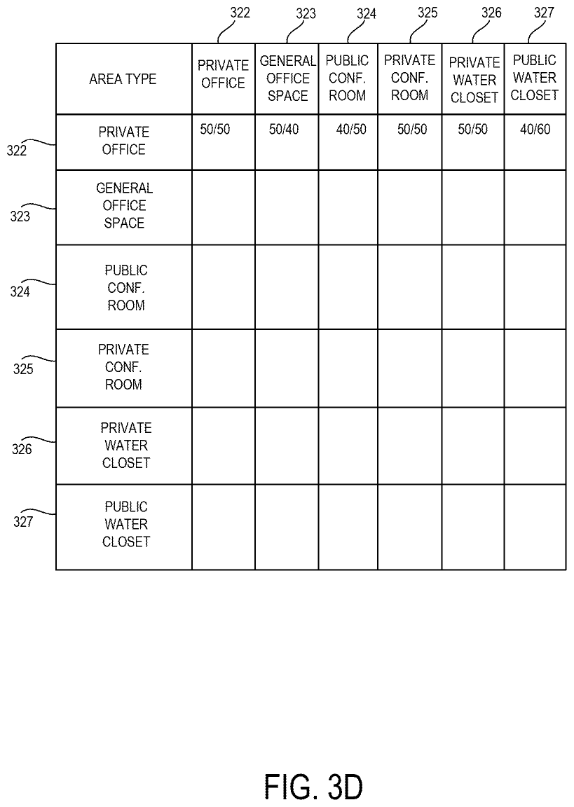

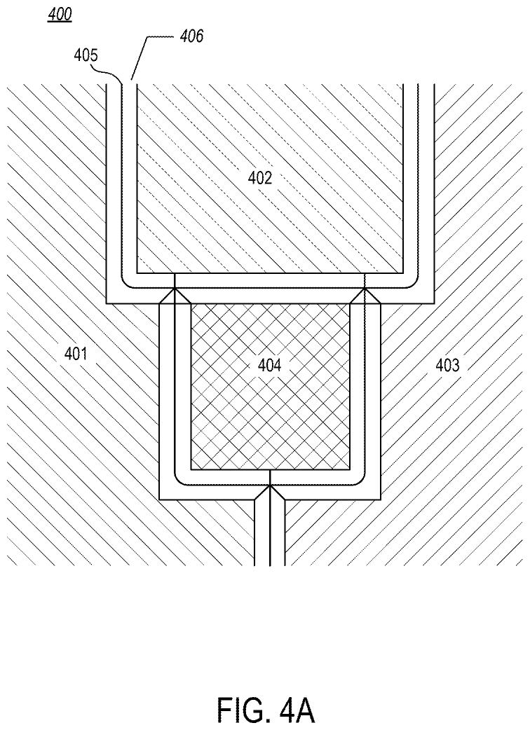

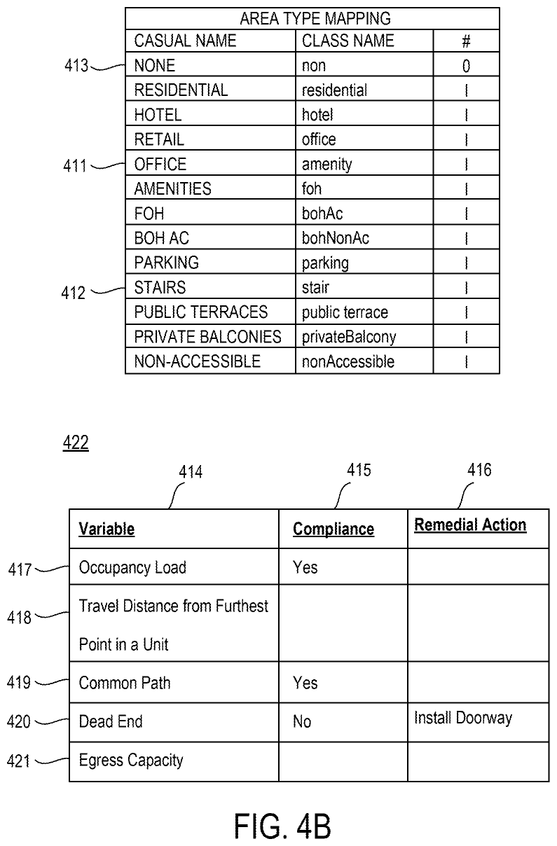

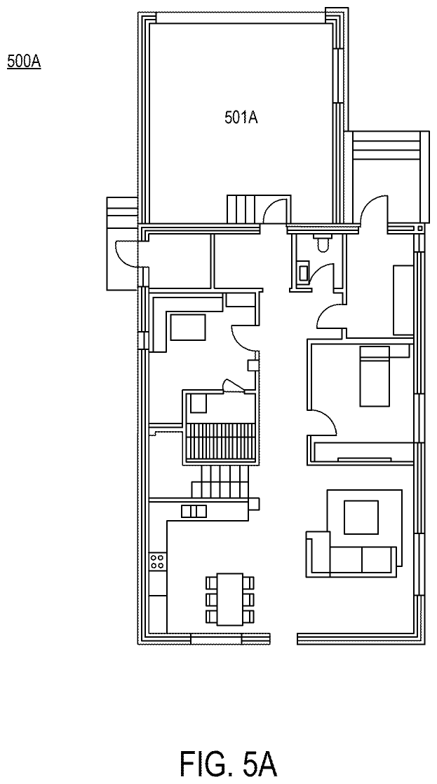

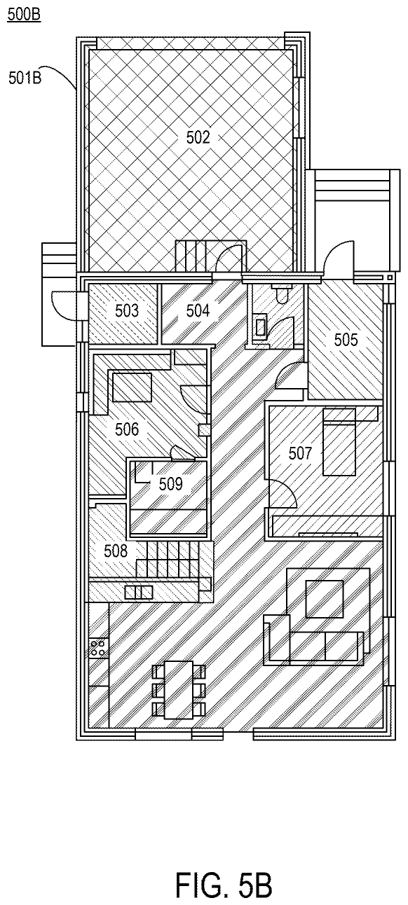

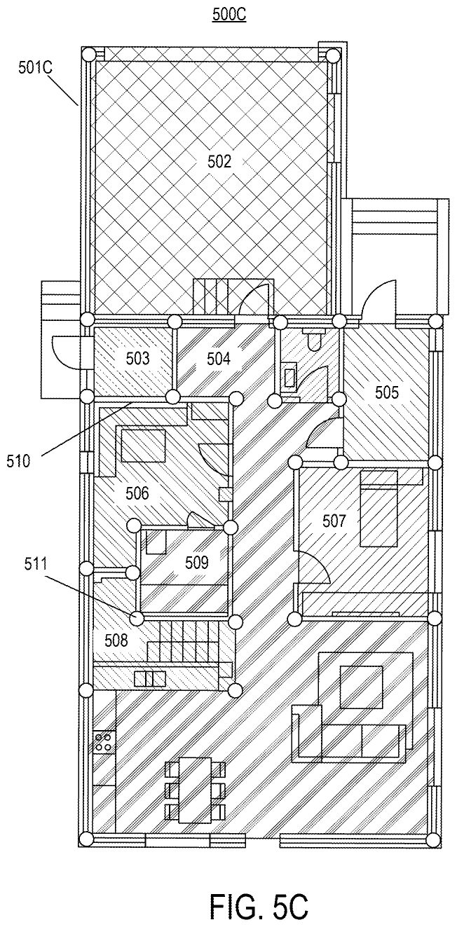

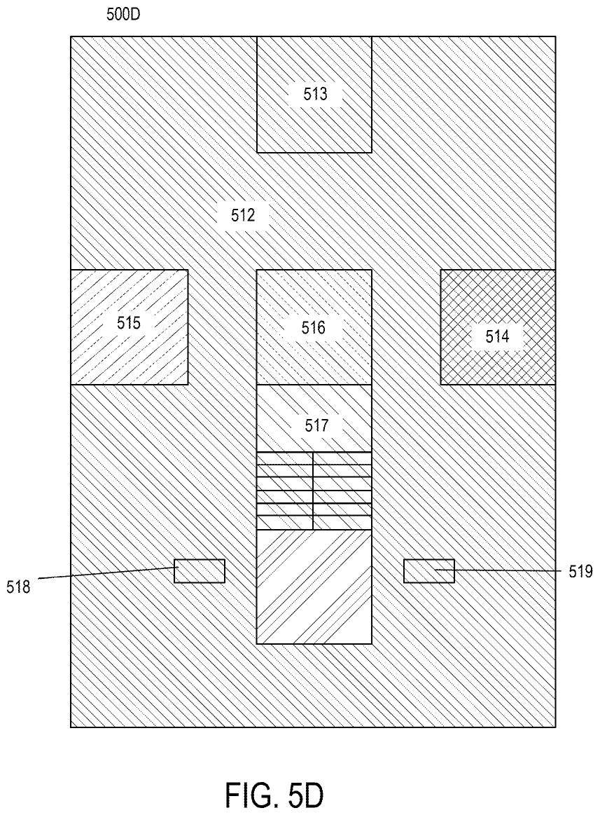

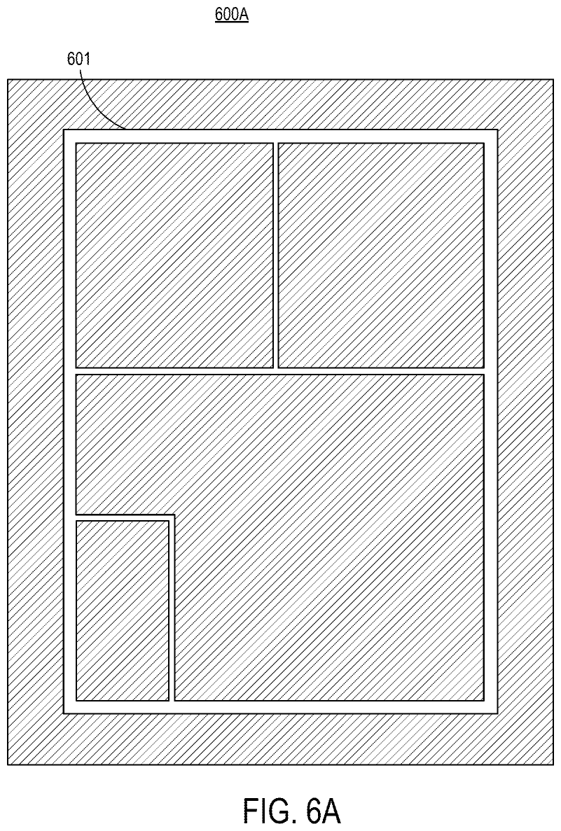

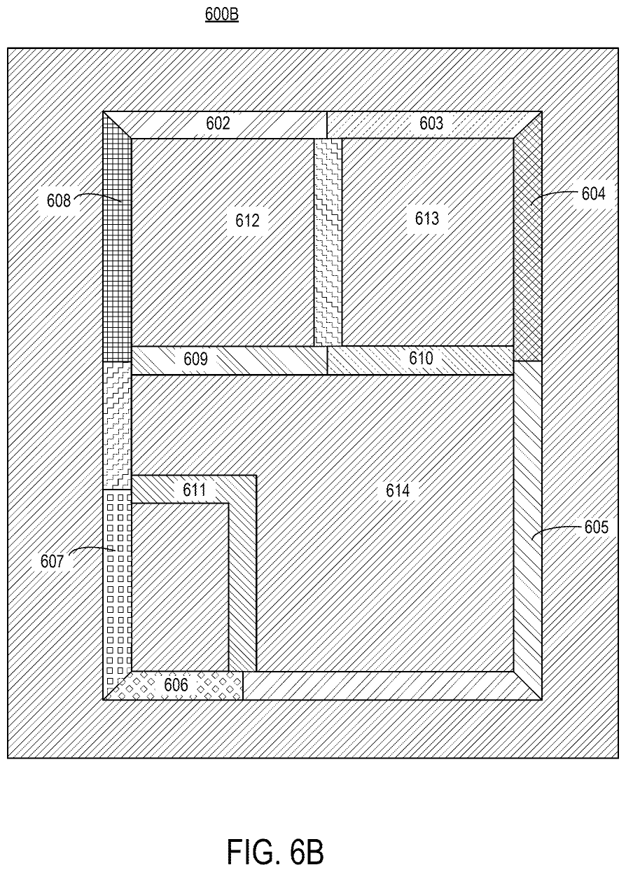

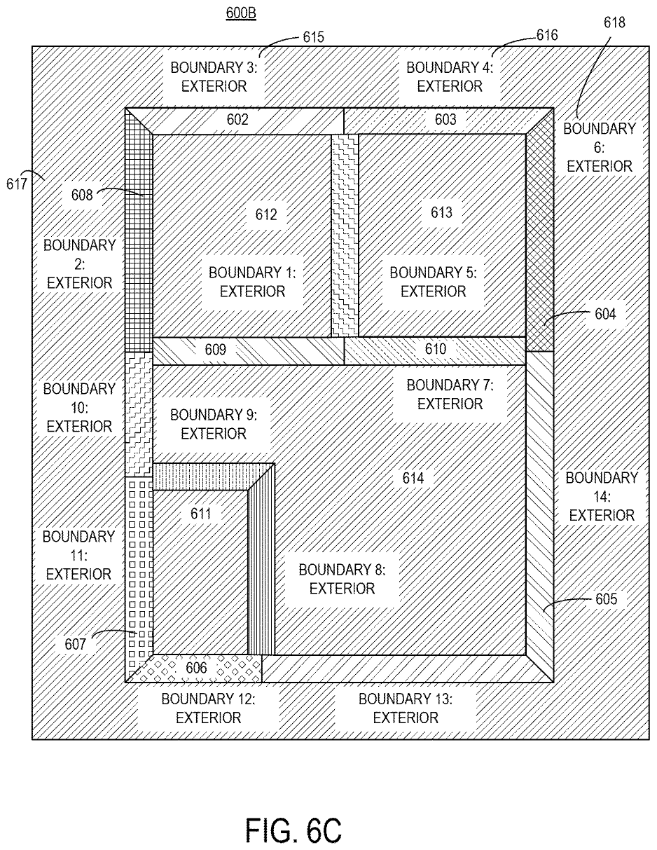

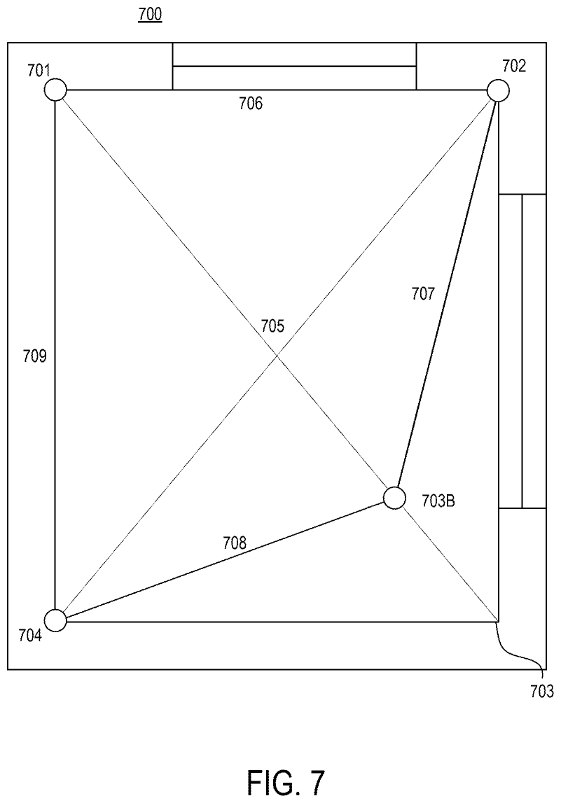

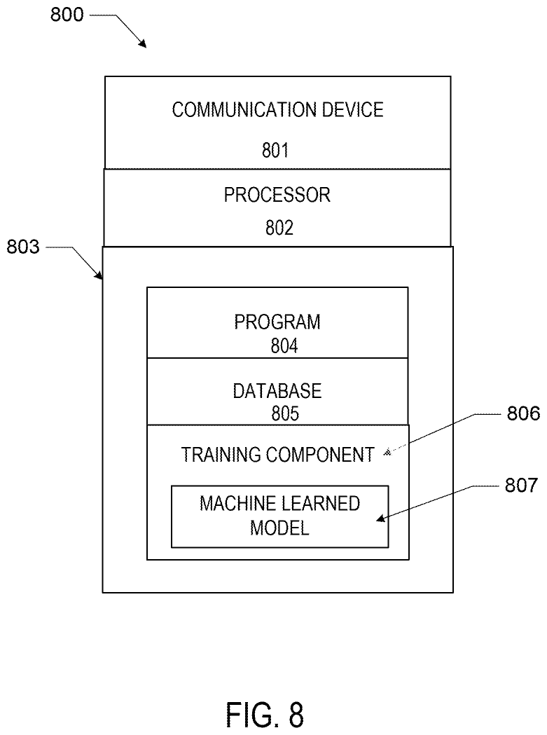

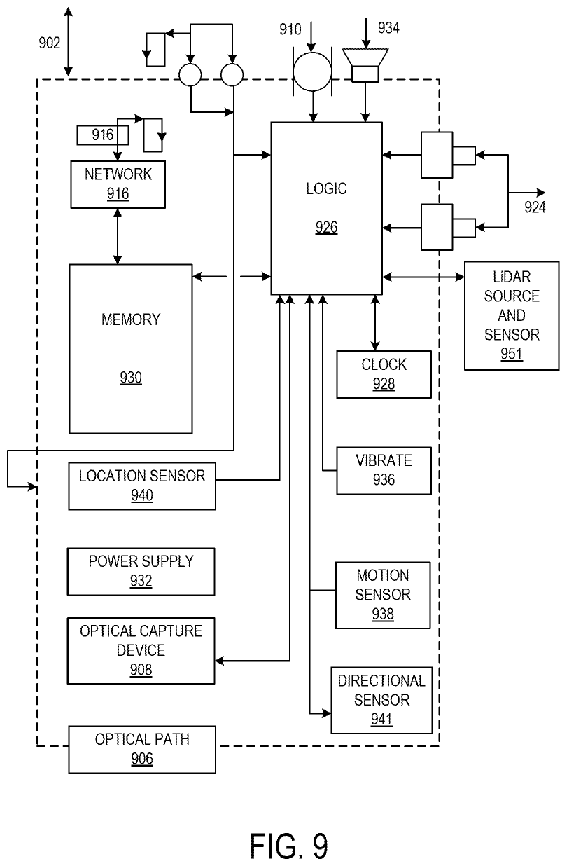

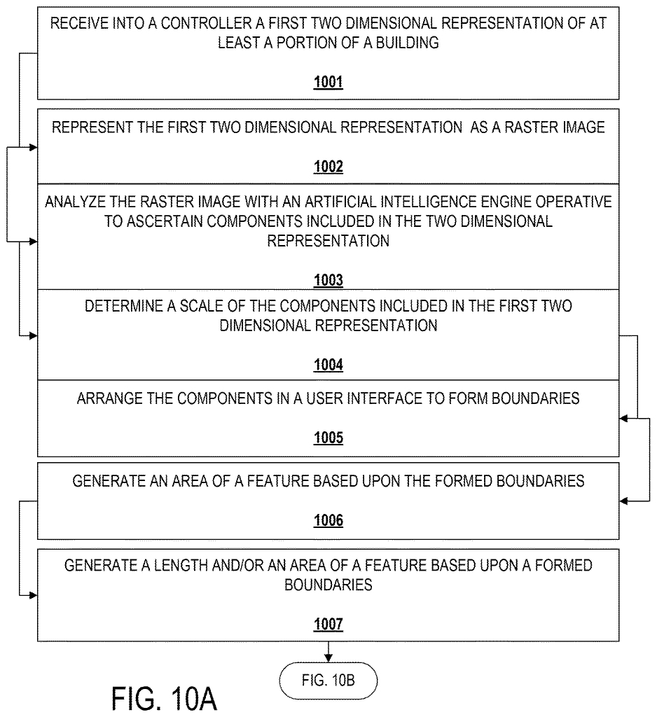

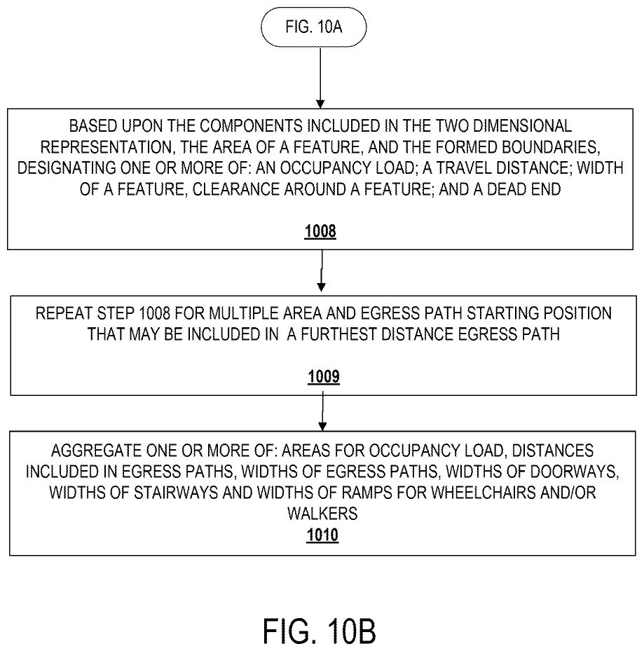

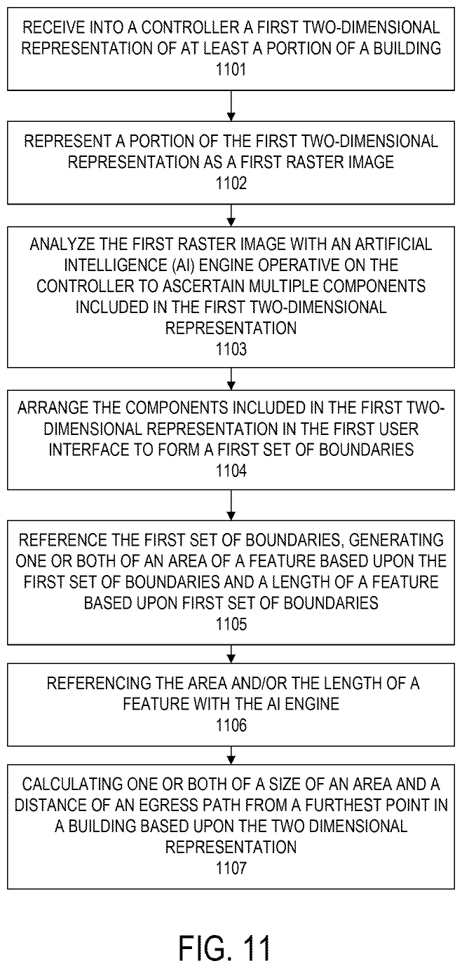

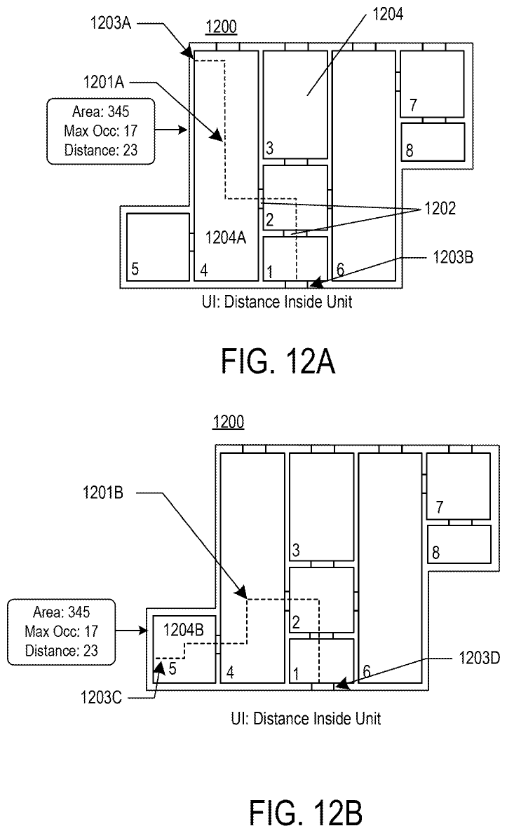

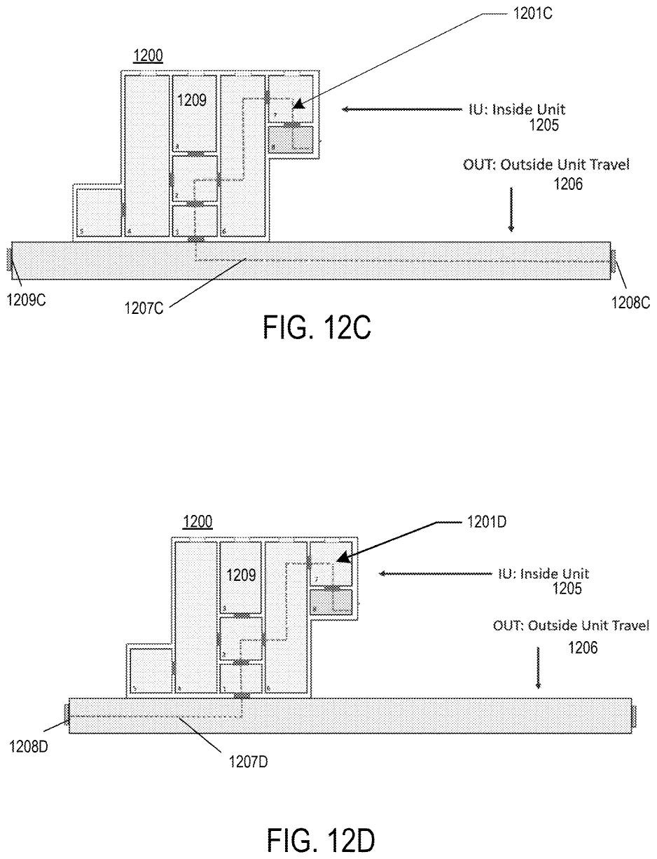

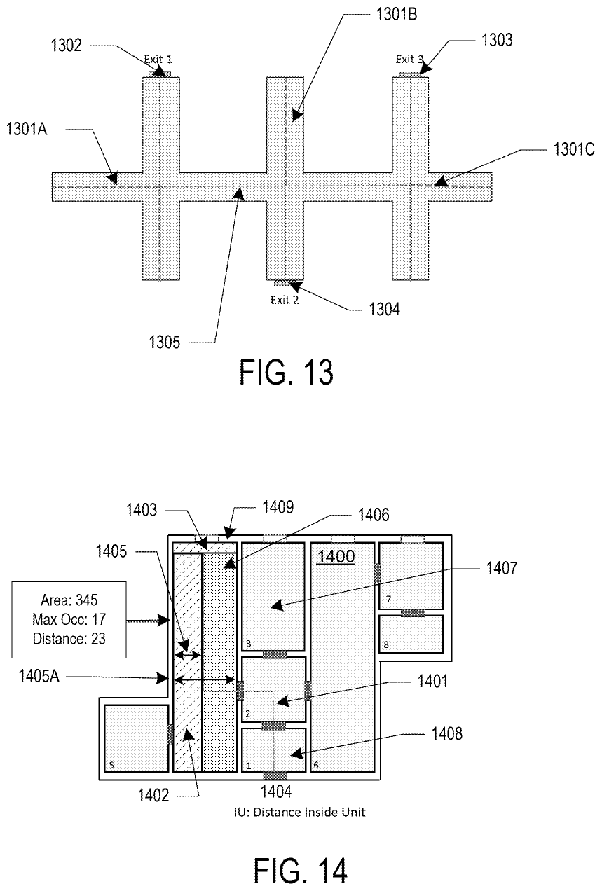

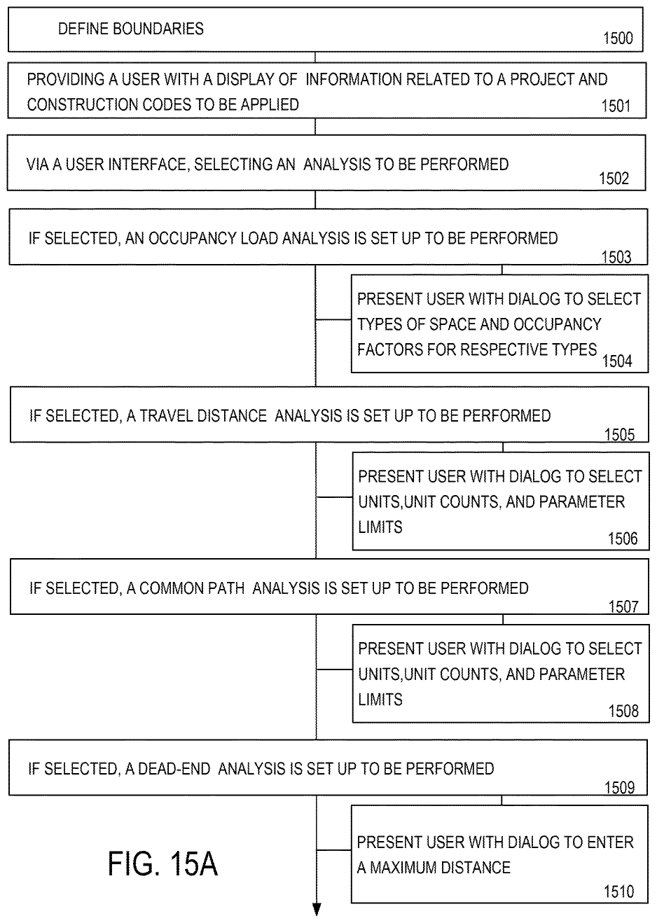

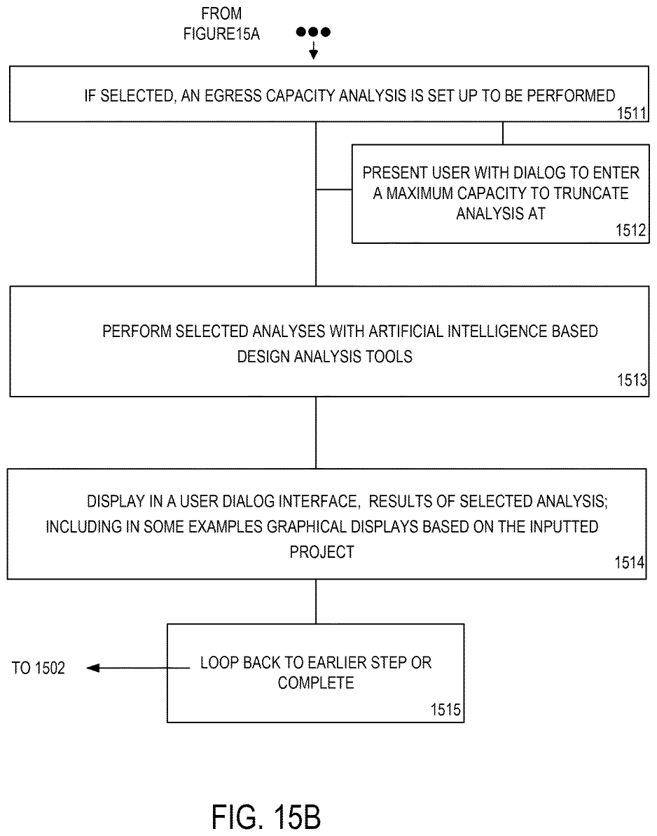

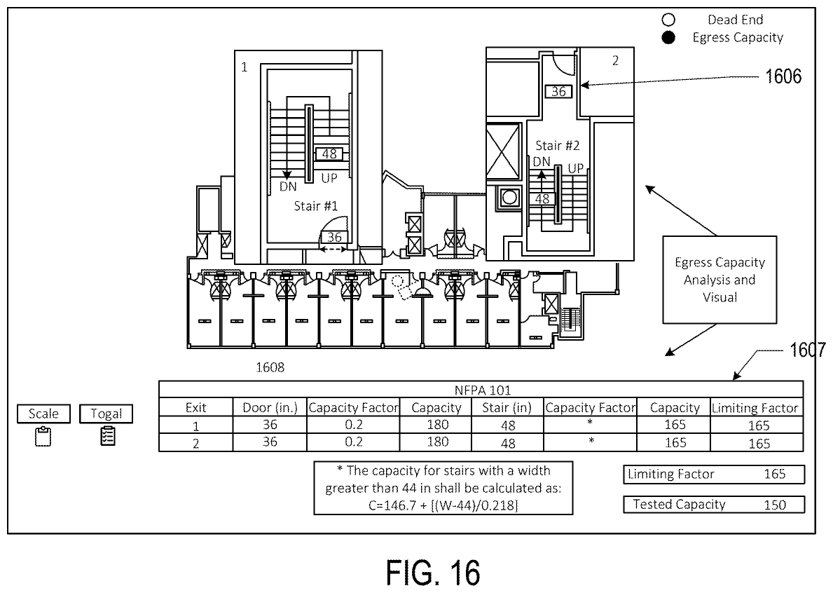

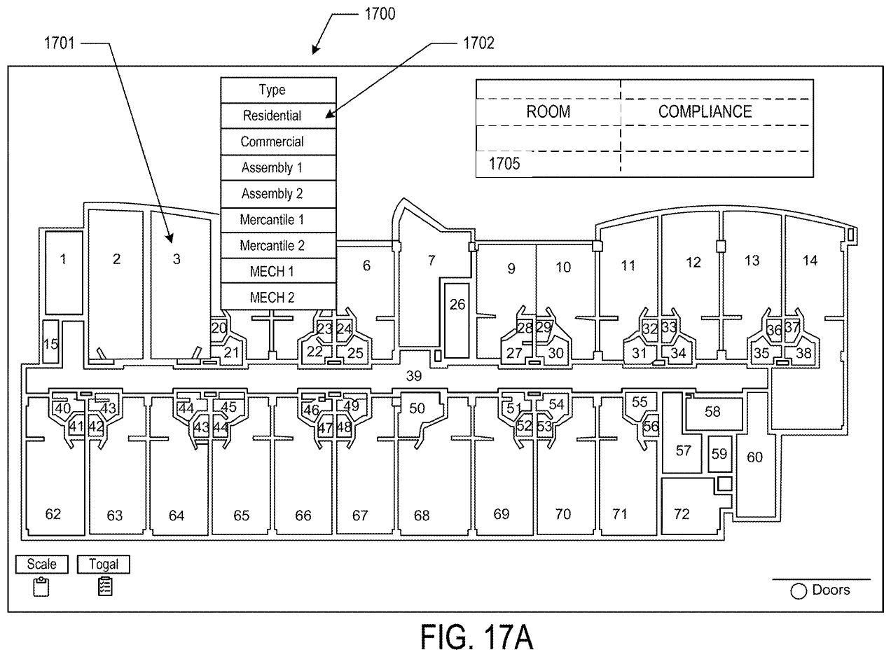

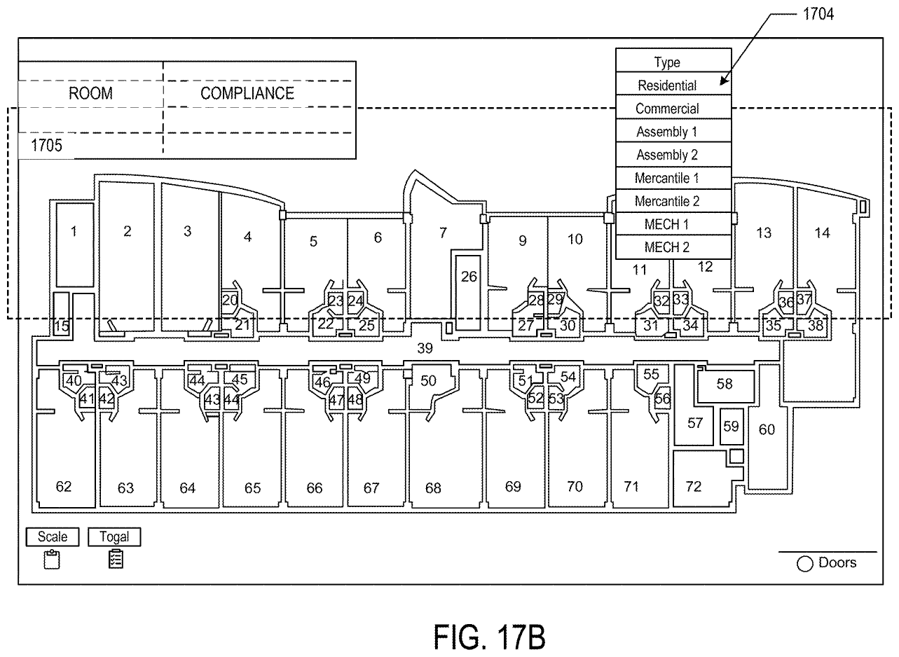

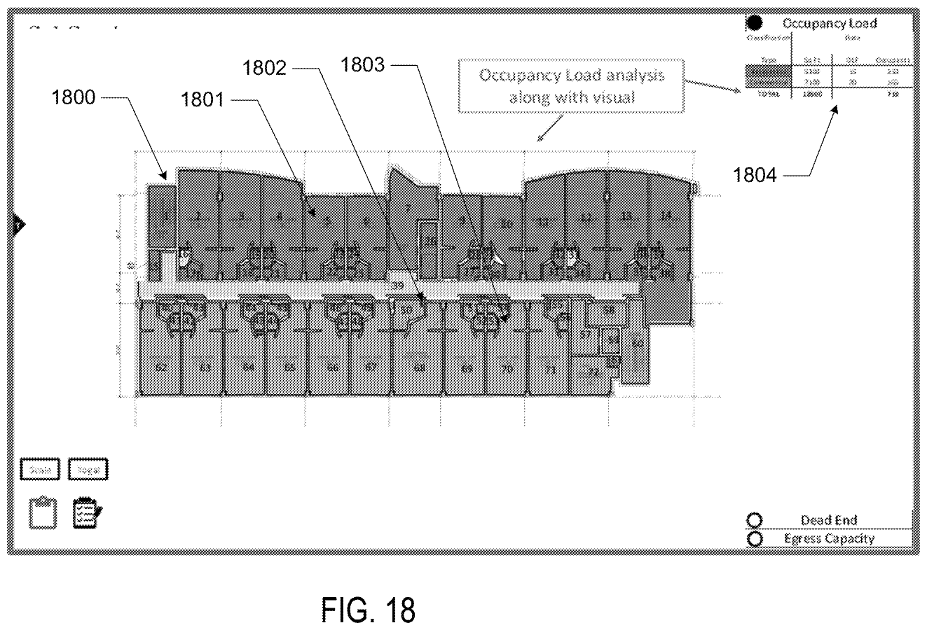

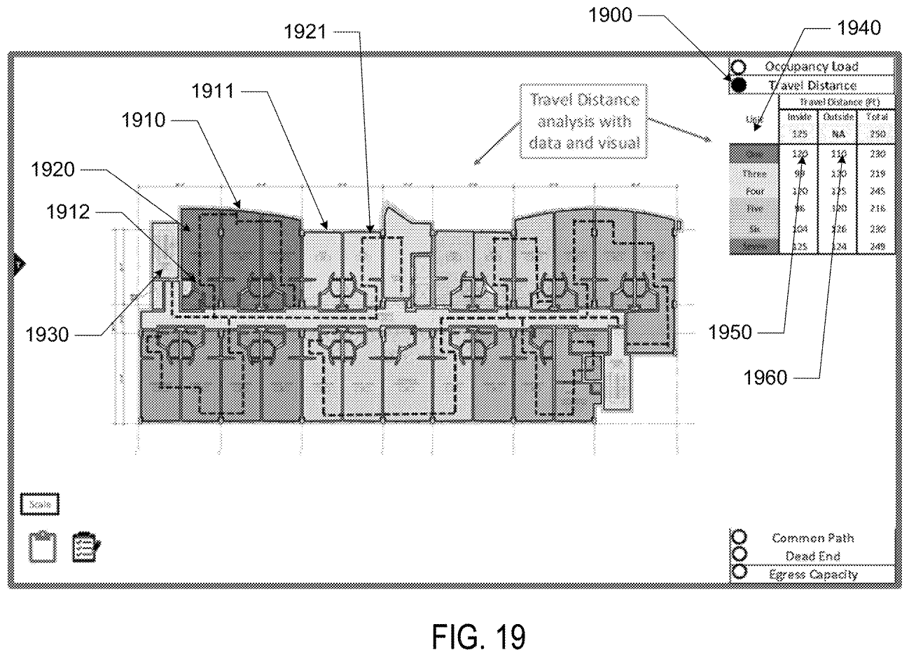

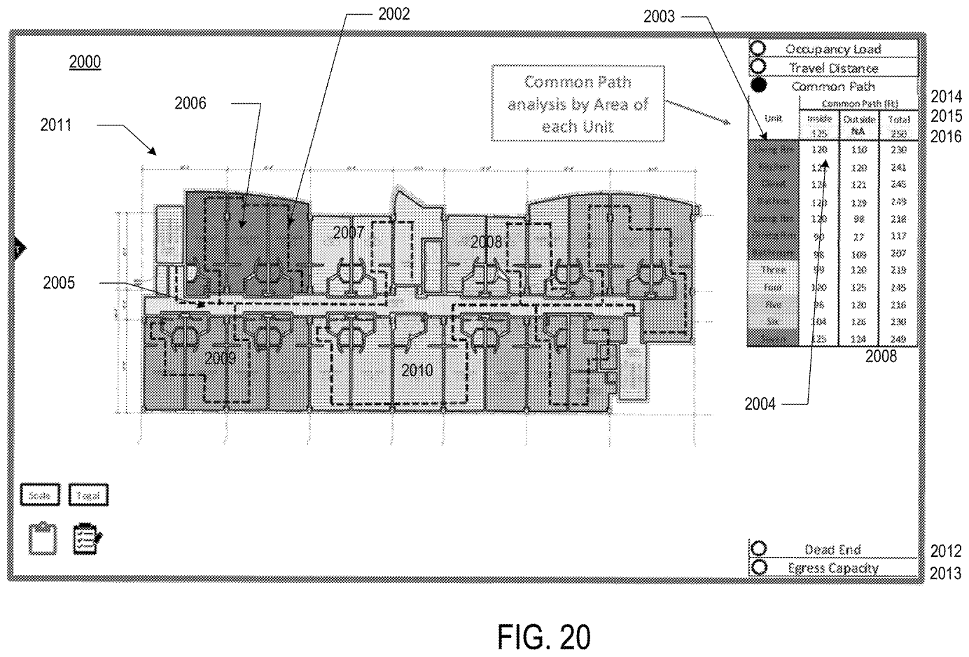

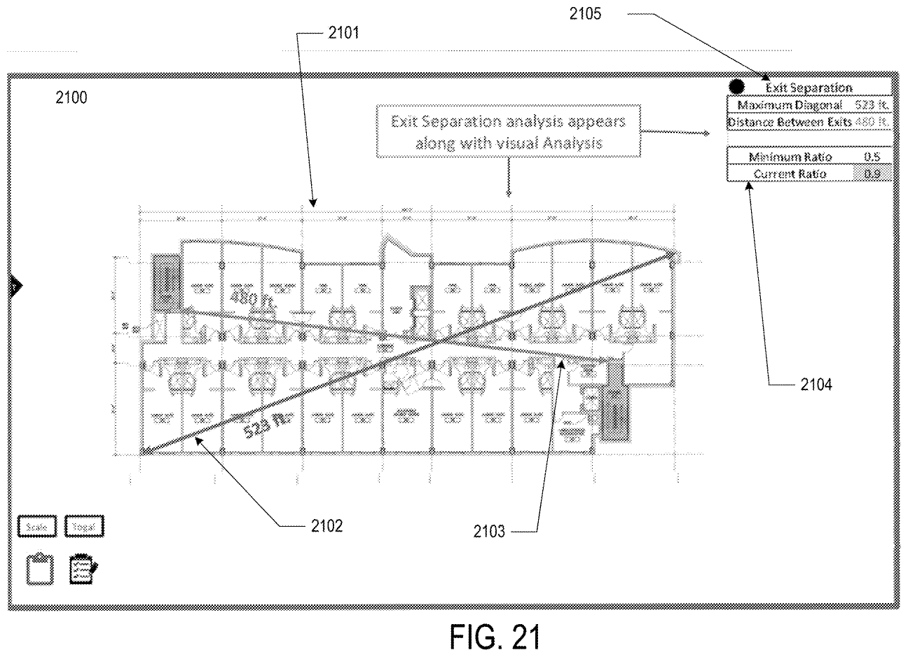

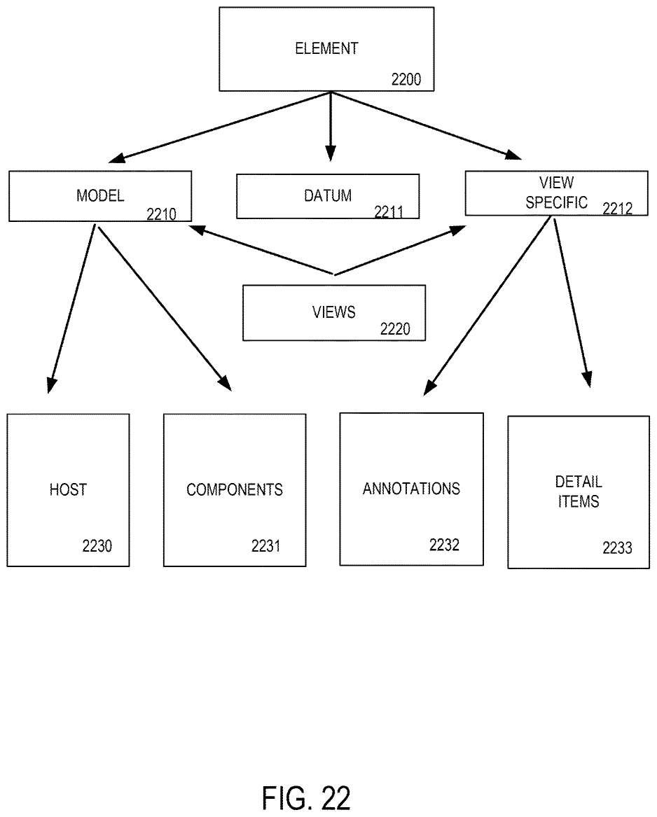

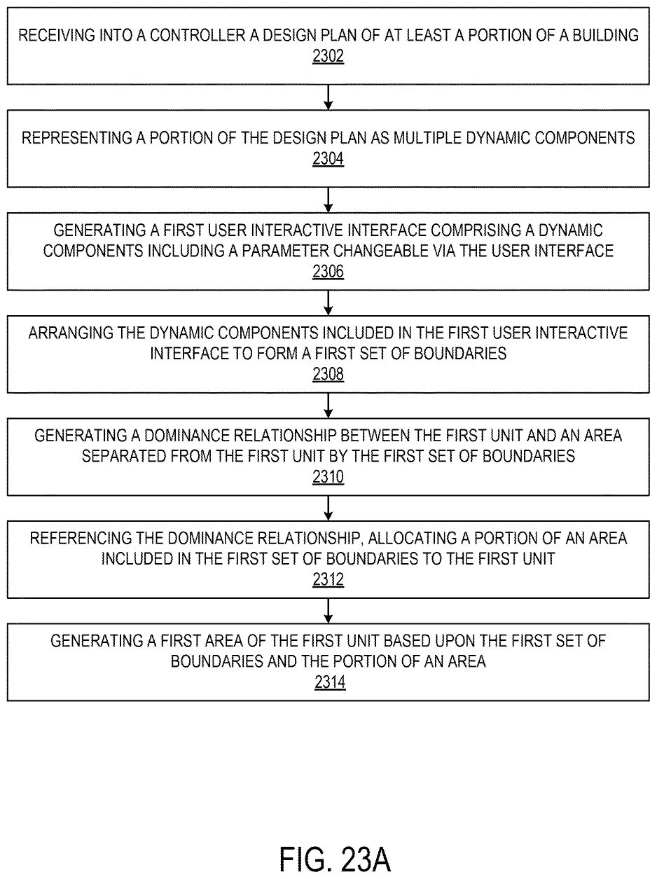

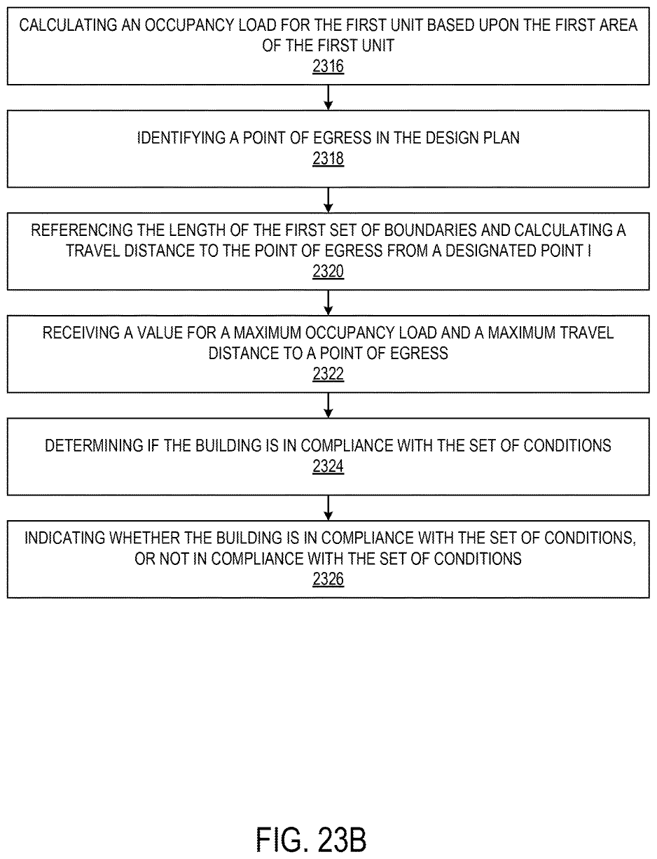

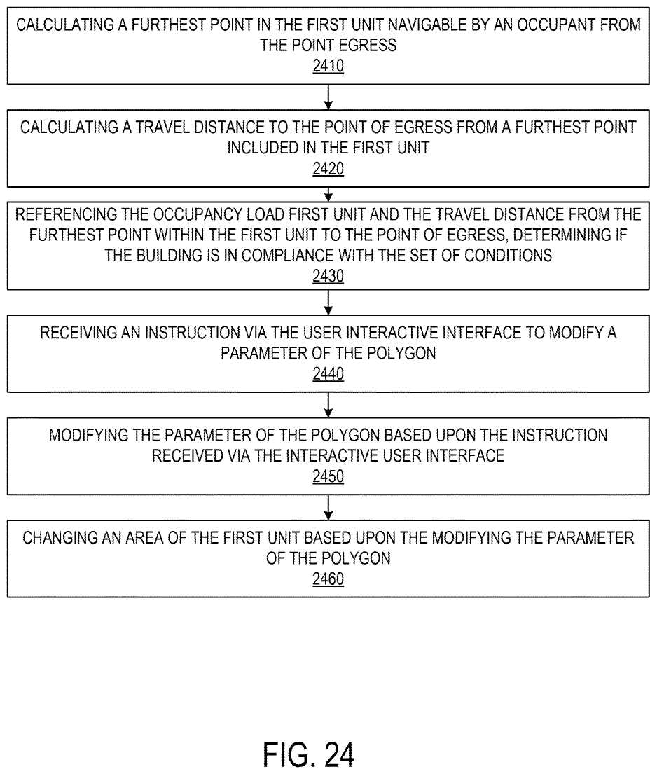

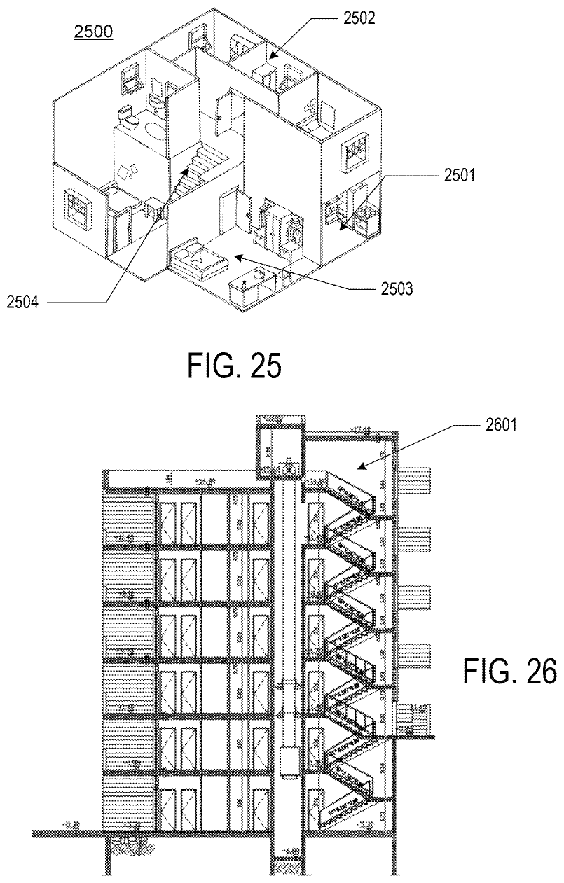

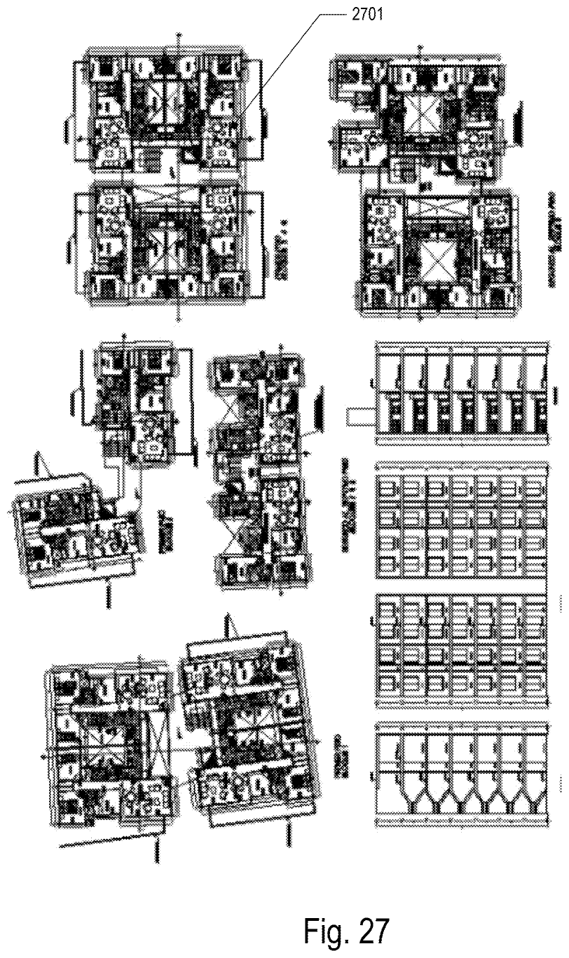

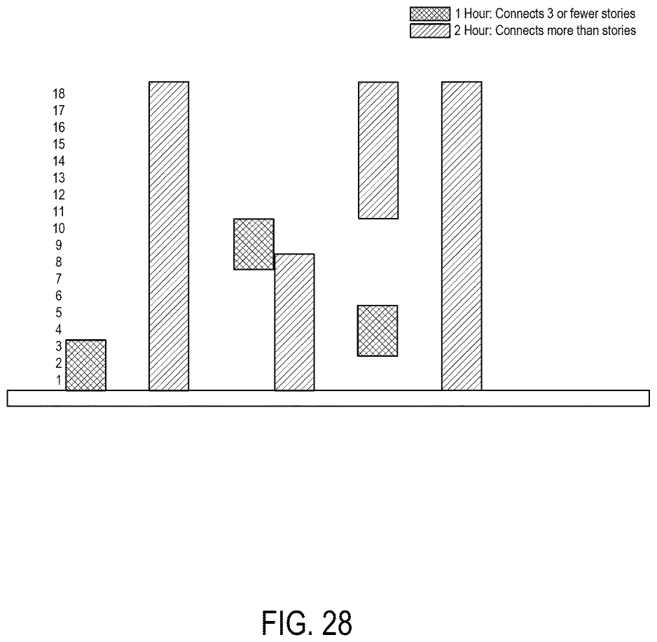

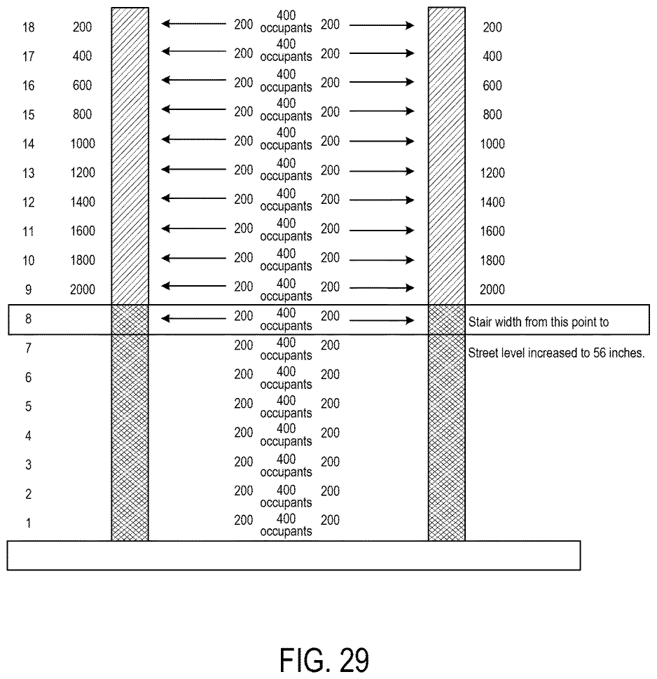

### DETAILED DESCRIPTION OF THE PREFERRED EMBODIMENTS

The present invention will now be described in detail with reference to exemplary embodiments thereof. The following description is presented to enable any person skilled in the art to make and use the invention. Specific details are set forth for purposes of explanation. However, it will be apparent to a person of ordinary skill in the art that these specific details are not required to practice the invention. In other instances, well-known structures and devices are shown in block diagram form in order to avoid unnecessarily obscuring the present invention.

The present invention provides improved methods and apparatus for artificial intelligence-based analysis of building design plans for regulatory compliance and for the automated generation, presentation, and verification of candidate correction pathways when compliance failures are detected. The invention is a Continuation-in-Part of the disclosure set forth in the parent applications identified in the Cross Reference to Related Applications section, including in particular the disclosure of AI-based analysis of building design plans for compliance with applicable codes, the generation of an interactive dynamic user interface based upon a two-dimensional design plan reference, the automated generation of suggested modifications to achieve compliance, the presentation of options for sets of changes to a floor plan that may be implemented in order to achieve compliance, and the iterative dynamic re-evaluation of a modified design plan to confirm compliance. The present invention adds to that disclosed subject matter new matter directed to the architecture and operation of a generative AI-based correction pathway pipeline, the construction and use of a failure context as the basis for querying a generative language model, the presentation of correction candidates as non-certified evaluation options with an associated liability-distinction modality, the iterative verification loop that re-runs compliance tests on a modified plan following candidate selection, and the autonomous regeneration of plan geometry as a further capability of the generative AI model.

The present invention operates in conjunction with an AI-based building design plan compliance analysis system of the type disclosed in the parent applications. For completeness of disclosure and to provide context for the new matter introduced herein, the following paragraphs summarize the relevant aspects of the AI-based compliance analysis foundation from which the detection-to-remediation pipeline of the present invention proceeds.

The AI-based compliance analysis system receives as input a design plan of at least a portion of a building. The design plan may include technical drawings such as blueprints, floor plans, architectural drawings, and the like in any supported file format, including without limitation DWG, DXF, PDF, TIFF, PNG, JPEG, and GIF formats, as well as BIM-compatible formats including RVT, IFC, and COBie formats. In embodiments where the design plan is in a vector format, the controller may transform the vector representation to a raster graphics image format suitable for AI engine processing. The controller may determine a pixel count of the resulting rasterized file and scale the image to a pixel count range appropriate for the AI engine.

The AI engine operative on the controller analyzes the design plan, or a rasterized representation thereof, to ascertain features and components present in the design plan. These features include, by way of non-limiting example, walls, doorways, windows, stairs, stairwells, hallways, plumbing fixtures, grab bars, ramps, and other architectural elements. The AI engine may employ deep learning artificial neural network techniques, machine learning, image segmentation, pattern recognition, and related computational methods to identify and classify features within the design plan. The AI engine may be trained on large numbers of design plans, including verified compliant and non-compliant examples, to improve the accuracy and reliability of feature recognition and compliance analysis.

The controller generates, based upon the AI engine's analysis of the design plan, an interactive user interface that presents a dynamic representation of the design plan to the user. The dynamic representation includes dynamic components corresponding to the architectural elements identified in the design plan. Each dynamic component is associated with parameters that may be modified by the user via the interactive user interface. For example, a user may adjust the dimensions of a room, reposition a fixture, modify the width of a doorway, or alter the length of an egress path directly within the interactive user interface. These user modifications are reflected in the dynamic design plan representation in real time, enabling immediate visualization of design changes.

The AI engine ascertains design parameters relevant to applicable code compliance from the dynamic components of the design plan. The AI engine compares the ascertained design parameters against conditions derived from one or more applicable building codes enforced by the authority having jurisdiction for the geographic location of the building. Building codes applicable to the compliance analysis may include, by way of non-limiting example, the Americans with Disabilities Act Accessibility Guidelines, the ANSI accessibility standards, the International Building Code, the National Fire Protection Association codes, the International Residential Code, the Uniform Plumbing Code, the National Electrical Code, the International Plumbing Code, and applicable local and state codes. The selection of applicable codes may be automated based on the geographic location of the building, user-specified, or both.

The compliance analysis generates, for each applicable code requirement evaluated, a compliance status indicating whether the design plan is in compliance with that requirement, in non-compliance with that requirement, or in a borderline or indeterminate state requiring further analysis. Compliance status may be presented in the interactive user interface using visual indicators such as color coding—for example, green for compliant elements and red or orange for non-compliant elements—together with textual explanations indicating the specific code requirement at issue, the measured or ascertained value for the relevant design parameter, and the required value or range specified by the applicable code. This foundational compliance analysis capability, including the generation of dynamic interactive interfaces with AI-derived compliance indicators across multiple code domains, is disclosed in the parent applications, and the present invention builds upon and extends that foundation.

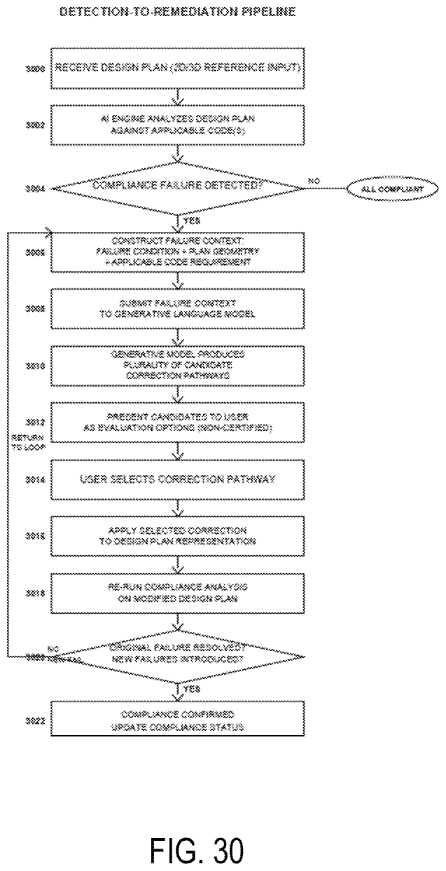

Referring now to FIG. 30, the present invention introduces a detection-to-remediation pipeline that takes as its starting point each compliance failure condition identified by the AI-based compliance analysis system described above and generates from that failure condition a plurality of candidate correction pathways using a generative language model. The detection-to-remediation pipeline comprises the following principal stages: failure detection and characterization; failure context construction; generative model querying; candidate correction pathway generation; candidate presentation and user selection; application of the selected correction; and iterative compliance re-evaluation. Each of these stages is described in detail in the paragraphs that follow, with reference to the pipeline stages 3000 through 3022 illustrated in FIG. 30.

In a failure detection and characterization stage, illustrated at steps 3000 through 3004 of FIG. 30, the compliance analysis system identifies one or more specific compliance failure conditions in the design plan under review. Each compliance failure condition is characterized by one or more of: the identity of the specific code section or requirement that is not met; the identity of the design element or elements involved in the failure; the measured or ascertained value of the relevant design parameter; the required value or range specified by the applicable code; and the geometric location of the failure condition within the design plan. This characterization is stored in a structured failure record accessible to the controller for use in the failure context construction stage. The failure record may include, by way of non-limiting example, a machine-readable description of the failure condition, a reference to the applicable code section, the geometry of the non-compliant design element as ascertained by the AI engine, and the spatial relationships between the non-compliant element and adjacent features in the design plan.

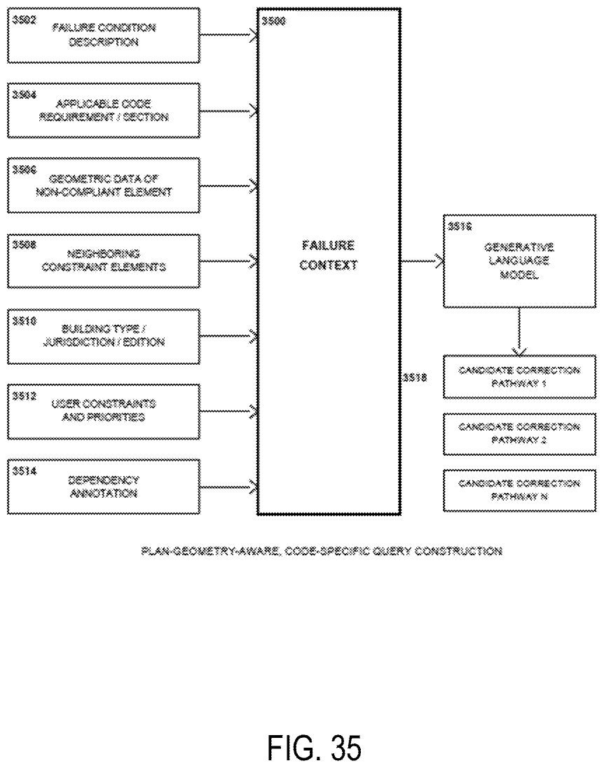

In the failure context construction stage, illustrated at step 3006 of FIG. 30 and shown in detail in FIG. 35, the controller constructs a failure context 3500 for each detected compliance failure condition. The failure context is a structured data representation that aggregates the information necessary for the generative language model to generate relevant and geometrically grounded candidate correction pathways for the specific failure at issue. The failure context may include one or more of: a natural language or structured description of the failure condition; a reference to the applicable code requirement, including the specific code section, the required threshold or parameter value, and any relevant tolerance or exception provisions; geometric data descriptive of the non-compliant design element, including its position, dimensions, orientation, and spatial relationships to adjacent design elements as ascertained by the AI engine from the design plan; a description of neighboring design elements that may constrain or affect possible corrections, such as load-bearing walls, adjacent fixture placements, clearance zones, or egress paths; information about the building type and applicable jurisdiction; and any user-specified constraints or priorities, such as aesthetic preferences, material specifications, or budget considerations that may be relevant to the types of correction options generated.

The failure context is not a generic query to the generative language model but is a plan-geometry-aware and code-specific representation of the particular failure condition encountered in the particular design under review. This specificity is essential to the utility of the correction pathways generated in response: generic correction advice for a type of failure provides limited value to a design professional seeking to resolve a specific failure in a specific building layout. By constructing a failure context that includes the actual geometry of the non-compliant element and its spatial relationships to adjacent features, the present invention enables the generative language model to generate correction candidates that are grounded in the actual constraints and possibilities presented by the design.

In the generative model querying stage, illustrated at step 3008 of FIG. 30, the controller submits the failure context to a generative language model. The generative language model may be a large language model, a transformer-based generative model, a fine-tuned domain-specific model trained on building code requirements, architectural design standards, and corrective design practice, or any other AI model capable of receiving the failure context and producing structured or natural-language descriptions of candidate design modifications responsive to the failure condition. The generative language model may be operated locally on the controller, on a remote server accessible to the controller via a network connection, or through a combination of local and remote processing resources. In some embodiments, the generative language model may be accessed through an application programming interface provided by an AI model service provider. In other embodiments, a specialized generative model may be trained on a corpus of building design plans, applicable code requirements, and verified compliance correction scenarios to optimize the quality and relevance of the correction pathways generated for building design plan compliance failures.

The generative language model receives the failure context and generates, in response, one or more candidate correction pathways, as illustrated at step 3010 of FIG. 30. In preferred embodiments, the generative language model generates a plurality of candidate correction pathways, each representing a distinct alternative approach to resolving the failure condition. The plurality of candidate correction pathways allows the user to evaluate multiple design alternatives and select the correction that best fits the specific requirements, constraints, and priorities of the project. The number of candidate correction pathways generated may be configurable by the user or by the system, and is not limited to any specific number. In illustrative examples, the generative language model may generate two, three, four, or more candidate correction pathways for a single failure condition. Different candidate correction pathways may involve different types of modifications for example, one candidate may involve enlarging a space, another may involve relocating a fixture, and a third may involve reclassifying an area for a different occupancy use—enabling the user to evaluate fundamentally different design approaches to resolving the same failure.

Each candidate correction pathway generated by the generative language model describes one or more modifications to the design plan that are calculated to resolve the failure condition. The description of each candidate correction pathway may include one or more of: a natural-language description of the proposed design modification; identification of the specific design element or elements to be modified; the proposed new value or configuration for the relevant design parameter, such as a proposed new dimension, position, orientation, or count; an explanation of how the proposed modification addresses the specific failure condition, including identification of the code requirement or requirements that the modification is expected to satisfy; an assessment of the potential impact of the proposed modification on other aspects of the design, including potential effects on adjacent design elements, egress paths, space allocations, or other compliance requirements; and, in embodiments where cost estimation is integrated, a preliminary cost estimate associated with implementing the proposed modification.

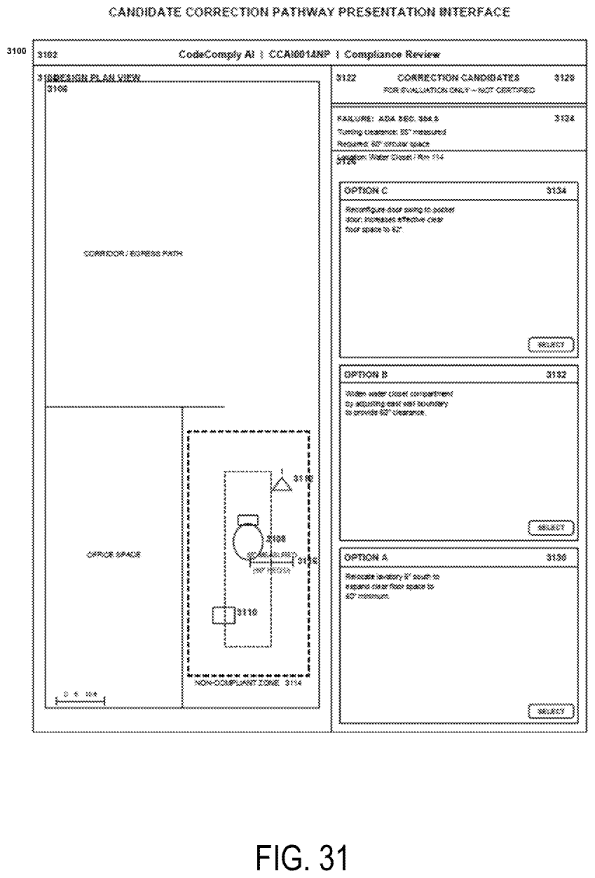

In the candidate presentation stage, illustrated at step 3012 of FIG. 30 and in the exemplary interface 3100 of FIG. 31, the controller presents the plurality of candidate correction pathways 3130, 3132, 3134 to the user via the interactive user interface. In preferred embodiments, the candidate correction pathways are presented within a panel or overlay integrated into the interactive user interface alongside the dynamic design plan representation, so that the user may view the failure location and the candidate options simultaneously. The presentation may include, for each candidate correction pathway, a summary description of the proposed modification, a visual indication on the design plan of the element or area to which the modification would be applied, and, in some embodiments, a preview of how the design plan would appear if the candidate correction were applied.

A critical feature of the candidate presentation stage, indicated at panel header 3122 of FIG. 31, is the modality in which the correction candidates are offered to the user. The plurality of candidate correction pathways are presented as options for the user to evaluate, not as certified compliant design solutions. Each presented candidate is explicitly identified as a proposed correction option subject to user evaluation and system verification, not as a determination that the proposed modification will result in a compliant design. This presentation modality reflects the fact that the generative language model generates correction candidates based on analysis of the failure context and the applicable code, but that the verification of the compliance of any selected correction is performed by the iterative compliance re-evaluation stage of the system rather than asserted at the point of candidate presentation. This distinction is both technically accurate and materially important from a liability standpoint: a system that presents AI-generated design modifications as certified compliant solutions would make representations about the ultimate compliance of user designs that the AI model is not positioned to guarantee without verification. The present invention avoids this problem by maintaining a clear distinction between the generation of correction candidates and the verification of their compliance through re-evaluation.

Upon user selection of one of the presented candidate correction pathways, illustrated at steps 3014 and 3016 of FIG. 30, the controller applies the selected correction to the dynamic design plan representation maintained by the system. Application of the selected correction involves modifying the dynamic components of the design plan representation that correspond to the design elements identified in the correction pathway. For example, if the selected correction pathway specifies relocating a lavatory fixture to increase clearance around a water closet, the controller modifies the position parameters of the dynamic component corresponding to the lavatory fixture in the design plan representation. If the selected correction pathway specifies increasing the width of a doorway, the controller modifies the dimension parameters of the dynamic component corresponding to that doorway. These modifications are applied to the dynamic design plan representation and presented to the user in the interactive user interface in real time, allowing the user to visualize the design as it would appear with the selected correction in place.

In some embodiments, the user may adjust the parameters of a selected correction pathway before applying it, or may select multiple elements of different candidate correction pathways to assemble a composite correction. The interactive user interface may include controls that allow the user to fine-tune the modifications proposed by the selected correction pathway, with the dynamic design plan representation updating in real time to reflect user adjustments. Any user-made adjustments to the correction are recorded and incorporated into the modified design plan representation that is submitted to the iterative compliance re-evaluation stage.

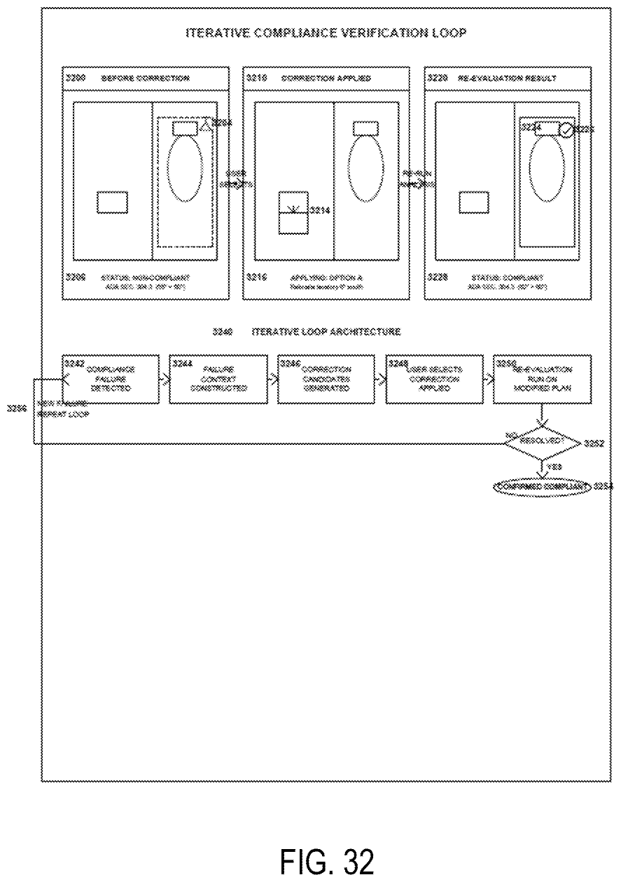

In the iterative compliance re-evaluation stage, illustrated at steps 3018 and 3020 of FIG. 30 and in FIG. 32, the controller automatically re-runs the relevant compliance analysis on the modified design plan representation following application of the selected correction pathway. The iterative compliance re-evaluation serves two principal purposes: first, to verify that the selected correction pathway resolves the original compliance failure condition that triggered the correction pathway generation; and second, to determine whether the applied correction introduces any new compliance failure conditions in the design plan.

The iterative compliance re-evaluation employs the same AI-based compliance analysis capabilities described above in the context of the initial compliance analysis. The AI engine re-analyzes the modified design plan representation, re-ascertains the relevant design parameters in the context of the applied correction, and re-compares those parameters against the applicable code requirements. The re-evaluation may be scoped to the area of the design plan affected by the applied correction or, in preferred embodiments, may encompass a broader analysis that includes compliance requirements potentially affected by the modification, including code requirements related to adjacent design elements, spatial relationships, occupancy load calculations, egress path calculations, and other compliance parameters that may be influenced by the applied change.

The results of the iterative compliance re-evaluation are presented to the user in the interactive user interface, as illustrated in the panels 3200, 3210, and 3220 and the loop architecture 3240 of FIG. 32. If the re-evaluation confirms that the selected correction resolves the original failure condition and does not introduce new violations, the system may indicate successful resolution through a visual compliance confirmation on the modified design plan and an updated compliance status in the compliance report. If the re-evaluation identifies that the applied correction does not fully resolve the original failure condition, or that the correction introduces one or more new compliance failure conditions, the system generates new failure context records for each unresolved or newly identified failure condition and may initiate a new cycle of the detection-to-remediation pipeline for those conditions. In this way, the iterative compliance re-evaluation drives a closed-loop compliance resolution process in which the user is supported at each step by AI-generated correction options and automated verification, continuing until all identified compliance failure conditions are resolved or until the user terminates the process.

The iterative nature of the correction and re-evaluation cycle distinguishes the present invention from prior art systems that generate a suggestion and leave the user to independently determine whether the suggestion actually resolves the failure. In the present invention, the system does not require the user to manually re-run a compliance check after applying a correction. The re-evaluation is automatic, immediate, and comprehensive, providing the user with reliable confirmation that the applied correction achieves its intended effect. This closed-loop architecture is a significant advancement in the efficiency and reliability of AI-assisted building design plan compliance workflows.

The detection-to-remediation pipeline of the present invention is not limited to any specific building code, code type, or type of compliance failure. The pipeline architecture described herein is applicable across any compliance test or code domain supported by the underlying compliance analysis engine. This code-agnostic generality is a deliberate and inventively significant design choice. Building design professionals must navigate compliance requirements across many code domains simultaneously, including accessibility, fire and smoke control, plumbing, electrical, structural, egress, energy efficiency, and local jurisdictional requirements. A correction pathway generation system that is applicable only within a single code domain provides limited value in this environment. The present invention provides correction pathway generation across all supported code domains within a single unified pipeline architecture.

By way of non-limiting illustration, the failure-context-to-correction-pathway pipeline of the present invention may be applied to compliance failures including: a water closet clearance dimension that fails to satisfy ADA minimum clearance requirements, where candidate correction pathways may include relocating the water closet, removing or repositioning an adjacent fixture, or reconfiguring the toilet compartment dimensions; a corridor width that fails to satisfy IBC minimum egress width requirements, where candidate correction pathways may include widening the corridor by adjusting adjacent wall boundaries, relocating partitions, or recommending an occupancy reclassification of the space; a plumbing fixture count that fails to satisfy IPC or UPC minimum fixture count requirements for a determined occupancy load and building use, where candidate correction pathways may include adding fixtures, modifying the space classification, or adjusting the occupancy load basis; a smoke management design that fails to satisfy NFPA requirements for egress path pressurization or compartmentation, where candidate correction pathways may include adding mechanical ventilation components, modifying horizontal or vertical fire barriers, or recommending changes to the spatial layout that improve passive smoke control; and a wheelchair turning clearance that fails to satisfy ADAAG minimum turning radius requirements, where candidate correction pathways may include enlarging the relevant space, removing obstructions within the turning clearance zone, or reconfiguring the layout of the space. These examples are illustrative and not limiting; the pipeline is applicable to any compliance failure condition across any code domain supported by the system.

In preferred embodiments, the detection-to-remediation pipeline of the present invention is applied to fire protection and life safety compliance analysis, including compliance analysis under codes and standards promulgated by the National Fire Protection Association, such as, by way of non-limiting example, NFPA 101 (Life Safety Code), NFPA 13 (Standard for the Installation of Sprinkler Systems), NFPA 72 (National Fire Alarm and Signaling Code), NFPA 80 (Standard for Fire Doors and Other Opening Protectives), NFPA 92 (Standard for Smoke Control Systems), NFPA 10 (Standard for Portable Fire Extinguishers), NFPA 14 (Standard for the Installation of Standpipe and Hose Systems), and corresponding provisions of the International Building Code and the International Fire Code as adopted by an authority having jurisdiction, in the editions applicable to the building location and project.

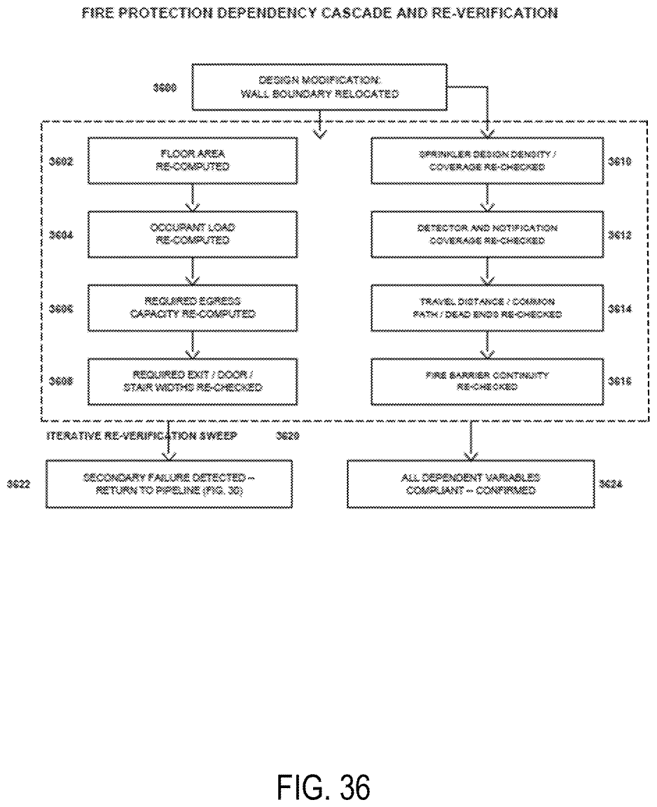

Referring to FIG. 36, fire protection compliance failures present a class of failure conditions in which multiple compliance variables are interdependent, such that a design modification resolving one failure condition may alter the value of one or more other fire protection variables. By way of non-limiting example, a modification to a wall boundary may alter a floor area, which alters a calculated occupant load, which alters a required egress capacity, which alters a required aggregate exit width, which may further alter a required sprinkler design density or notification appliance coverage. The iterative compliance re-evaluation stage of the present invention is of particular utility in the fire protection domain because, upon application of a selected correction pathway, the system automatically re-computes all fire protection variables dependent upon the modified design elements and re-evaluates each affected compliance requirement, thereby detecting any secondary failure conditions introduced by the correction before the design proceeds.

In some embodiments, the AI engine performs life safety compliance tests upon the design plan including one or more of: determining an occupant load for each space based upon an area of the space as ascertained by the AI engine and an occupant load factor associated with a use classification of the space; determining a required egress capacity based upon the occupant load and an applicable capacity factor; comparing an available egress width of each door, corridor, and stairway along an egress path against the required egress capacity; determining a travel distance from a most remote point in a space to a nearest exit and comparing the travel distance against a maximum travel distance permitted for the occupancy classification and sprinkler protection status of the building; determining a common path of travel and comparing it against an applicable common path limit; determining a length of each dead-end corridor and comparing it against an applicable dead-end limit; determining a separation distance between exits or exit access doorways and comparing the separation against a minimum fraction of the maximum overall diagonal dimension of the area served, as required for exit remoteness; and determining a door swing direction for each egress door and comparing the swing direction against requirements applicable to the occupant load served by the door.

When a life safety compliance failure is detected under any test recited in the preceding paragraph, the failure context constructed by the controller includes the geometric basis of the failure, including, as applicable: the boundaries and area of the space at issue; the location of the most remote point and the path geometry to each available exit; the widths of doors, corridors, and stairways along each egress path; the locations and separations of exits serving the area; the occupancy classification and occupant load factors applied; and the sprinkler protection status of the relevant area. The generative language model receives this failure context and generates a plurality of candidate correction pathways, which may include, by way of non-limiting example: adding an exit or exit access doorway at a candidate location identified from the plan geometry; widening one or more doors, corridors, or stairways; reorienting a door swing; subdividing a space to reduce the occupant load served by a constrained egress element; relocating an exit to increase exit separation; shortening or eliminating a dead-end corridor by adding a connecting path or relocating a partition; and reducing a travel distance by adding an intermediate exit or reconfiguring the path geometry.

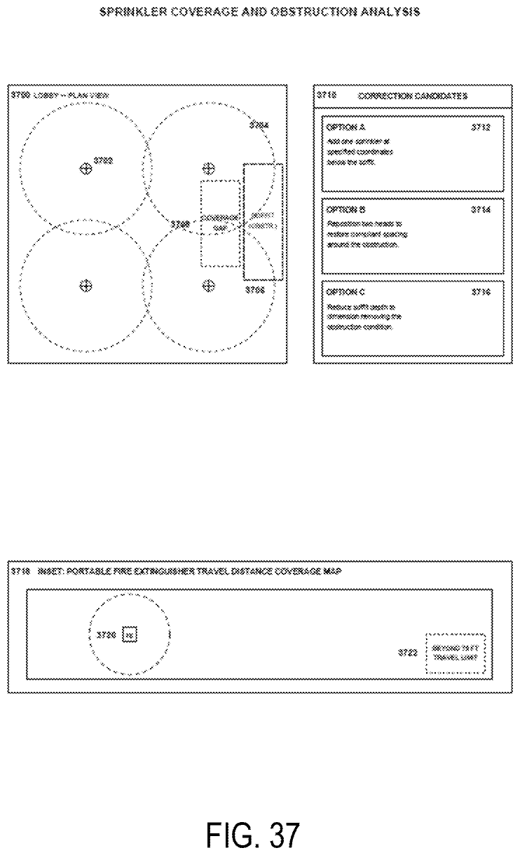

In some embodiments, illustrated in FIG. 37, the AI engine performs automatic sprinkler system compliance tests upon the design plan, including one or more of: inferring a hazard classification for each space based upon the use of the space as ascertained from the design plan and associated metadata, the hazard classification including, by way of non-limiting example, light hazard, ordinary hazard group 1, ordinary hazard group 2, and extra hazard classifications; determining a coverage area and spacing for each sprinkler identified in the design plan and comparing the coverage area and spacing against maximums permitted for the sprinkler type and hazard classification; performing an obstruction analysis identifying structural members, soffits, ductwork, lighting fixtures, and other elements ascertained from the design plan that obstruct a sprinkler discharge pattern in violation of applicable obstruction rules; determining the applicability of small room provisions to spaces qualifying under the applicable standard; and verifying that the sprinkler design density and remote design area assumptions associated with the system are consistent with the hazard classification of the spaces protected.

When a sprinkler compliance failure is detected, the failure context includes, as applicable: the ceiling geometry of the affected space; the positions, types, and coverage characteristics of affected sprinklers; the positions and dimensions of obstructing elements; the hazard classification of the space and the basis for that classification; and the relationships between the affected space and adjacent protected spaces. Candidate correction pathways generated by the generative language model for sprinkler failures may include, by way of non-limiting example: adding one or more sprinklers at candidate positions calculated to restore compliant coverage; repositioning an existing sprinkler relative to an obstruction; relocating or resizing the obstructing element where the obstruction is a relocatable design feature; substituting an alternative sprinkler type, such as an extended coverage or sidewall sprinkler, where permitted; and reclassifying the space use where the failure arises from a hazard classification inconsistent with the intended use of the space.

In some embodiments, the AI engine performs fire alarm and signaling compliance tests upon the design plan, including one or more of: determining a spacing and placement of smoke detectors and heat detectors relative to ceiling geometry, including adjustments for ceiling height, beam pockets, sloped ceilings, and air handling outlets, and comparing the placement against applicable spacing rules; determining a coverage of audible and visible notification appliances relative to the spaces served, including consideration of room dimensions and intervening barriers, and comparing the coverage against applicable audibility and visibility requirements; and determining a placement of manual fire alarm boxes relative to exits and a maximum travel distance from any point in the building to the nearest manual fire alarm box.

Candidate correction pathways generated for detection and notification failures may include, by way of non-limiting example: adding a detector at a candidate position calculated from the ceiling geometry; repositioning a detector to account for a beam pocket or air handling outlet identified in the design plan; adding a notification appliance in a coverage gap identified by the analysis; upgrading a notification appliance rating where coverage is marginal; and relocating a manual fire alarm box to satisfy the travel distance requirement, with the candidate location selected from wall positions adjacent to exits identified in the plan geometry.

In some embodiments, the AI engine performs opening protective and fire barrier compliance tests, including one or more of: tracing the continuity of fire barriers, fire partitions, and smoke barriers identified in the design plan and detecting discontinuities; identifying each opening in a rated assembly and comparing the protective rating of the door, window, or damper assembly serving the opening against the rating required for the assembly; and verifying clearances and hardware requirements for fire door assemblies. Candidate correction pathways for barrier and opening failures may include upgrading a door assembly rating, relocating an opening out of a rated assembly, rerouting a barrier to restore continuity, and adding a protected vestibule.

In some embodiments, building upon the smoke management analysis disclosed in the parent applications, the AI engine performs smoke control compliance tests including identification of atriums and other vertical openings, verification of smoke zone boundary integrity, and assessment of the feasibility of pressurization of stairwells and elevator shafts. Candidate correction pathways for smoke control failures may include adding smoke barriers at candidate locations, specifying mechanical exhaust or pressurization capacities, and reconfiguring atrium geometry to reduce the affected area below thresholds triggering more stringent requirements.

In some embodiments, the AI engine performs portable fire extinguisher and standpipe compliance tests, including computing a travel distance coverage map, illustrated in the inset 3718 of FIG. 37, indicating, for each point in the design plan, the travel distance to the nearest fire extinguisher location, and comparing the maximum travel distance against the applicable limit; and determining, for each floor of a building required to have a standpipe system, whether each portion of the floor is within the required reach of a hose connection. Candidate correction pathways may include adding or relocating extinguisher cabinets at candidate wall positions and adding hose connections or relocating a standpipe riser.

In the fire protection domain, as illustrated in the dependency cascade and re-verification sweep 3620 of FIG. 36, the iterative compliance re-evaluation stage of the present invention re-computes, upon application of a selected correction pathway, each fire protection variable dependent upon a modified design element. By way of non-limiting example, where a selected correction subdivides a space to reduce occupant load, the re-evaluation re-computes the occupant load of each resulting space, the required egress capacity of each egress element serving each resulting space, the travel distances and common paths within each resulting space, the detector and notification coverage of each resulting space in view of the new partition, the sprinkler coverage in view of the new partition, and the continuity of any rated assembly affected by the new partition. The re-evaluation thereby detects secondary failure conditions, such as a new partition obstructing a sprinkler discharge pattern or interrupting notification appliance coverage, that would otherwise remain latent until formal review by the authority having jurisdiction.

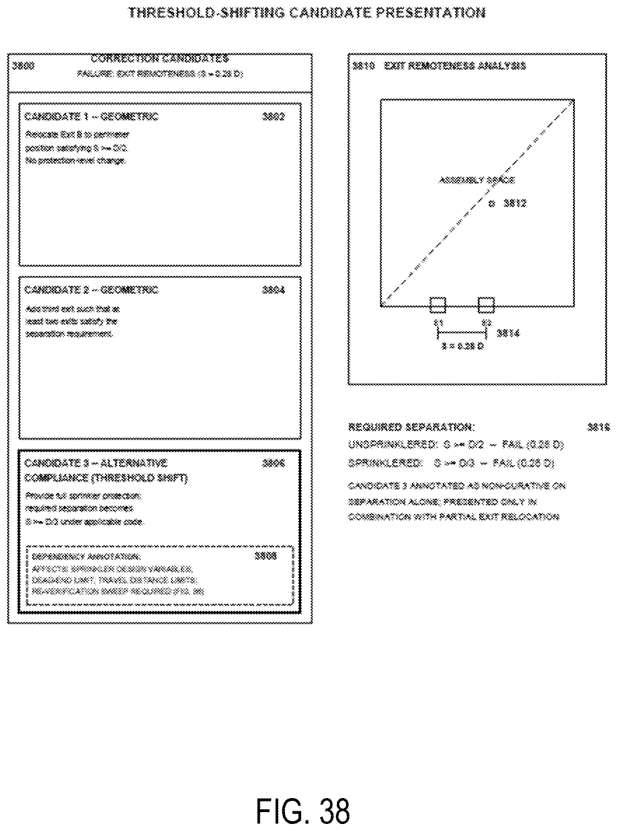

In some embodiments, the failure context submitted to the generative language model for a fire protection failure includes a dependency annotation (illustrated at 3514 of FIG. 35 and at annotation badge 3808 of FIG. 38) identifying other fire protection variables dependent upon the design elements implicated in the failure. The generative language model may use the dependency annotation to favor candidate correction pathways that resolve the failure condition with minimal disruption to dependent variables, and to annotate each candidate correction pathway with an identification of the dependent variables expected to be affected by the candidate. The presentation of candidate correction pathways to the user may include the dependency annotations, enabling the user to evaluate not only whether a candidate resolves the immediate failure but also the breadth of secondary re-verification the candidate will entail.

In a further exemplary embodiment, illustrated in part by the candidate presentation of FIG. 38, an architect uploads a mixed-use building design plan, and the AI engine detects a dead-end corridor of 35 feet in length on the second floor, exceeding the 20-foot dead-end limit applicable to the unsprinklered occupancy under the adopted edition of NFPA 101. The failure context includes the corridor geometry, the locations of the spaces served by the corridor, the locations of the nearest exits and exit access doors, and the sprinkler protection status of the floor. The generative language model generates three candidate correction pathways: a first candidate adding an exit access door at the dead end connecting to an adjacent exit stair, eliminating the dead-end condition entirely; a second candidate relocating a storage room partition to connect the dead-end corridor to a parallel corridor, converting the dead end to a through path; and a third candidate identifying that sprinkler inclusion on the floor would raise the applicable dead-end limit to 50 feet under the applicable code, presenting full-floor sprinkler protection as an alternative compliance strategy with an annotation that this candidate affects sprinkler system design variables and requires re-verification of sprinkler coverage. The architect selects the second candidate; the controller applies the partition relocation to the dynamic design plan representation, and the iterative re-evaluation confirms elimination of the dead-end condition, re-computes the affected egress paths and travel distances, verifies that the relocated partition does not obstruct any sprinkler or interrupt notification coverage, and confirms that no new failure conditions are introduced.

In a further exemplary embodiment, illustrated in the exit remoteness inset 3810 of FIG. 38, the AI engine detects that two exits serving an assembly space are separated by a distance equal to 28 percent of the maximum overall diagonal dimension of the space, failing the applicable exit remoteness requirement of one-half the diagonal for an unsprinklered building. The failure context includes the space boundary geometry, the diagonal dimension, the exit locations, and the sprinkler protection status. The generative language model generates candidate correction pathways including: relocating one exit to a candidate position along the perimeter identified from the plan geometry as satisfying the one-half diagonal separation; adding a third exit such that at least two of the three exits satisfy the separation requirement; and an alternative compliance candidate noting that sprinkler protection of the building would reduce the required separation to one-third of the diagonal, which the existing configuration would not satisfy at 28 percent, with the candidate accordingly annotated as non-curative on separation alone and presented only in combination with a partial exit relocation. The user selects the first candidate; upon application, the iterative re-evaluation confirms the remoteness requirement is satisfied and re-verifies the travel distances, common paths, and egress capacities affected by the relocated exit.

In a further exemplary embodiment illustrating the autonomous plan geometry regeneration capability in the fire protection domain, the AI engine detects a sprinkler coverage gap 3708 caused by a soffit obstruction 3706 in a renovated lobby, as illustrated in FIG. 37. The generative language model, configured for autonomous geometry output, generates candidate correction pathways including structured geometric parameters specifying: a first candidate adding one sprinkler at specified coordinates below the soffit; a second candidate repositioning two existing sprinklers at specified coordinates to restore compliant spacing around the obstruction; and a third candidate reducing the soffit depth to a specified dimension that removes the obstruction condition. Each candidate is presented with a preview rendering. Upon user selection of the first candidate, the controller applies the new sprinkler position directly to the dynamic design plan representation and the iterative re-evaluation confirms compliant coverage and verifies that the added sprinkler does not conflict with lighting fixtures or ductwork identified in the plan.

Referring to FIG. 35, the failure context 3500 submitted to the generative language model 3516 is a structured representation, assembled from data elements 3502 through 3514, that enables the generative model to produce correction candidates that are meaningfully tailored to the specific failure condition in the specific design plan under review. In a preferred embodiment, the failure context is constructed as a structured prompt or query that may include: a concise description of the compliance failure, identifying the code requirement at issue, the measured parameter value, and the required parameter value or threshold; a geometric description of the non-compliant design element and its immediately surrounding design context, expressed in terms usable by the generative model to reason about spatial constraints and possible modifications; identification of any neighboring design elements that are likely to constrain or be affected by a correction to the non-compliant element; the building type, jurisdiction, and applicable code edition; and any user-specified design priorities or constraints relevant to the generation of correction options.

The geometric description of the non-compliant design element may be derived from the AI engine's analysis of the design plan and may include, by way of non-limiting example, the dimensions and position of the non-compliant element, the dimensions and positions of adjacent walls, fixtures, clearance zones, and egress paths, and the spatial relationships among these elements as determined by the AI engine. The inclusion of this geometric context in the failure context enables the generative language model to generate correction candidates that are geometrically feasible in the context of the actual design, rather than generic corrections that may not be applicable to the specific layout at issue.

In some embodiments, the failure context may further include examples of similar failure conditions encountered in previously analyzed design plans and the correction pathways that were applied to resolve those conditions, derived from a database of past compliance analyses maintained by the system. The inclusion of such examples may improve the relevance and quality of the correction candidates generated by the generative language model by providing the model with analogical reasoning material from which to derive correction options appropriate to the current failure context. The database of past compliance analyses may be updated continuously as the system processes design plans and records user-selected corrections and the results of iterative compliance re-evaluations, enabling the system to improve its correction pathway generation capabilities over time through accumulated operational experience.

A preferred embodiment of the present invention generates a plurality of candidate correction pathways for each compliance failure condition, and presents those candidates to the user as distinct alternative options for evaluation. This multi-option output architecture reflects several important principles of the invention.

First, a single compliance failure condition may be resolvable through fundamentally different design approaches, each of which may have different implications for the overall building design, user experience, aesthetic character, construction cost, and compliance with other code requirements. Presenting multiple distinct correction alternatives enables the design professional to evaluate these trade-offs and select the correction that best serves the overall design objectives of the project, rather than being directed to a single correction approach determined by the system.

Second, the generative language model that produces the correction candidates operates on a probabilistic basis and may identify multiple plausible corrections without being able to certify the relative compliance merit of each candidate without further analysis. The multi-option presentation correctly reflects this aspect of generative model output by offering candidates for evaluation rather than asserting a single correct answer.

Third, the iterative compliance re-evaluation stage of the pipeline applies automated compliance verification to the user-selected correction, which provides the verification that the presented candidate actually achieves compliance. This verification function enables the system to present multiple correction candidates without asserting compliance of any particular candidate at the point of presentation, with the assurance that the selected correction will be automatically verified before the design proceeds.

The interactive user interface component of the candidate presentation stage may include visual indicators, summary descriptions, and in some embodiments preview renderings of the proposed design modifications for each candidate correction pathway. A user may compare the presented candidates, expand the description of any candidate to view additional detail, and select any candidate for application. Upon selection, the controller applies the selected correction to the dynamic design plan representation and initiates the iterative compliance re-evaluation. If the user is not satisfied with any of the presented candidates, the user may request additional correction pathway options, and the controller may submit a modified or expanded failure context to the generative language model to generate additional candidates.

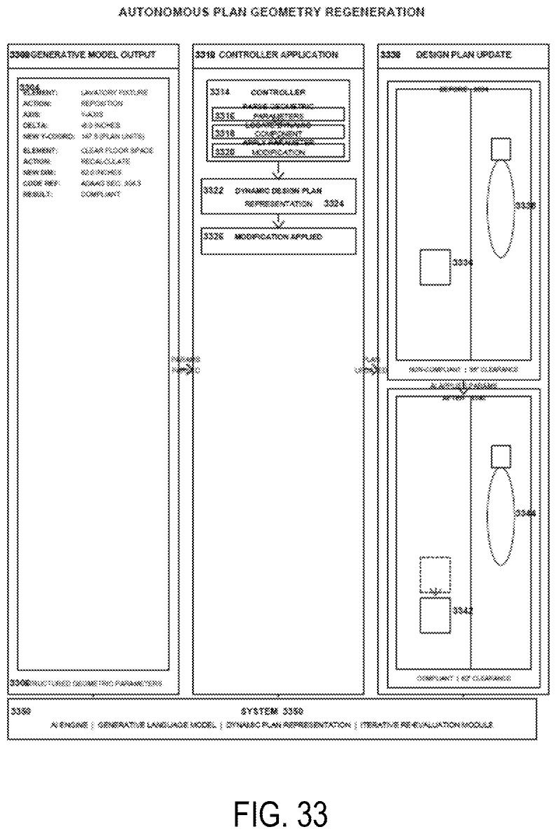

In a further embodiment, illustrated in FIG. 33, the present invention provides for autonomous regeneration of the affected portion of the design plan geometry, rather than merely describing a correction that the user or an external tool would need to implement. In this embodiment, the generative model output includes not only a natural-language or structured description of the proposed correction but also specific geometric parameters, coordinate positions, dimension values, or other plan element data that are directly applicable to the dynamic design plan representation maintained by the system. The controller applies these geometric parameters directly to the dynamic components of the design plan representation, resulting in automatic modification of the relevant design elements without requiring the user to manually implement the correction within a separate CAD or BIM tool.

The autonomous plan geometry regeneration capability of the present invention represents a further significant advancement over prior art correction suggestion systems. In prior art systems, a suggestion that an architect widen a corridor by two feet requires the architect to open the relevant CAD or BIM tool, locate the corridor boundaries, modify the wall positions, and regenerate the dependent elements of the design. In the present invention, the system automatically applies the modification to the dynamic design plan representation, enabling the architect to immediately view the modified design and proceed to the iterative compliance re-evaluation stage without manual intervention in a separate tool.

The generative model employed in the autonomous plan geometry regeneration embodiment, illustrated at 3300 through 3350 of FIG. 33, may be configured to output correction parameters in a structured format that the controller parses and applies to the dynamic design plan representation. The structured format may specify, for example, one or more of: new position coordinates for a fixture or design element; new dimension values for a wall segment, doorway, clearance zone, or room boundary; new area or polygon boundary definitions for a modified space; removal or addition of design elements; or other geometric modifications applicable to the dynamic components of the design plan representation. The controller may apply these modifications through the same dynamic component modification mechanisms supported by the interactive user interface, providing that the autonomous plan geometry regeneration is consistent with the dynamic design plan representation architecture of the system.

The detection-to-remediation pipeline of the present invention integrates with and extends the compliance analysis and dynamic interface capabilities disclosed in the parent applications. The parent applications disclose, among other things: a system and method for receiving a design plan of at least a portion of a building; analyzing the design plan using an AI engine to ascertain design parameters and evaluate compliance with applicable code requirements; generating an interactive user interface that presents dynamic components representing the design plan and visual indicators of compliance status; supporting user modifications to dynamic components within the interactive user interface; and supporting iterative re-evaluation of a design plan in response to user modifications. The present invention adds to these capabilities the novel generative AI-based correction pathway pipeline that transforms each identified compliance failure into a set of AI-generated correction candidates, and the iterative compliance re-evaluation loop that automatically verifies the effectiveness of a user-selected correction.

The parent application CCAI0004CNT1 and its priority chain disclose, in particular, the concept of providing users with suggested changes and options for sets of changes to the floor plan that may be implemented in order to achieve compliance, as well as the concept of automated systems generating proposed modifications to achieve compliance with an applicable code. The present invention extends these concepts from the domain of rule-based or manually specified suggestions to AI-generated, plan-geometry-aware, multi-option correction pathway generation using a generative language model, with automated iterative compliance verification.

The parent application CCAI0001PCT-US discloses, in particular, dynamic re-evaluation allowing users to make iterative changes to the design parameters and immediately re-check compliance, with the system updating compliance status in real time to reflect changes made by the user. The present invention extends this iterative re-evaluation concept from a user-driven modification cycle to an AI-assisted correction cycle in which the system generates the correction options and automatically re-evaluates compliance upon user selection and application of a correction, without requiring the user to independently devise the correction approach or manually trigger the re-evaluation.

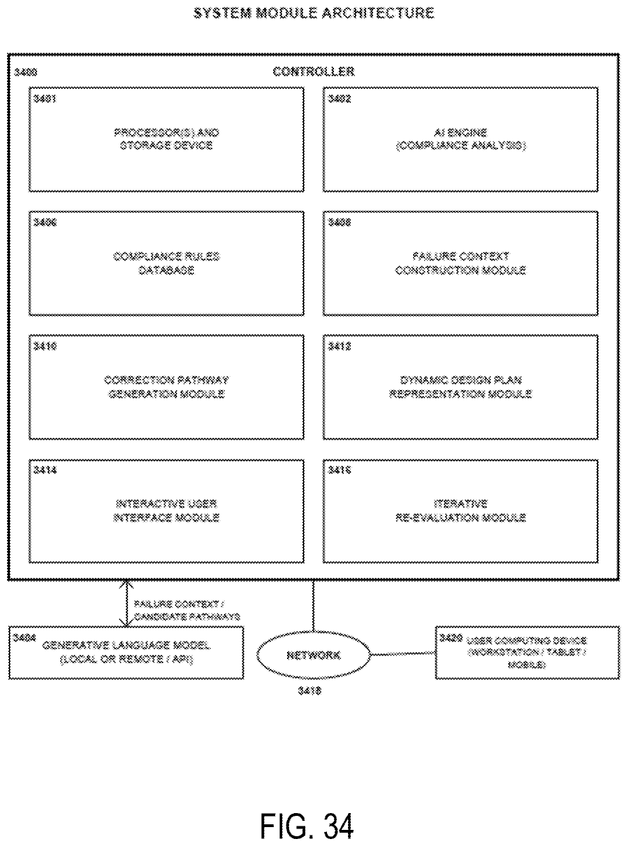

In a preferred embodiment, illustrated in FIG. 34, the system of the present invention comprises a controller 3400 including one or more processors 3401, a storage device, and network connectivity; an AI engine 3402 operative on the controller and configured to perform building design plan compliance analysis as described herein; a generative language model 3404 accessible to the controller, either locally deployed or accessible via a network API; a compliance rules database 3406 maintained by the controller and updated with current code requirements for applicable jurisdictions and code editions; a failure context construction module 3408 operative on the controller to assemble failure context records from compliance failure characterizations generated by the AI engine; a correction pathway generation module 3410 operative on the controller to manage queries to the generative language model and receive and parse correction pathway outputs; a dynamic design plan representation module 3412 operative on the controller to maintain a modifiable representation of the design plan and apply corrections to dynamic components; an interactive user interface module 3414 operative on the controller to present the design plan representation, compliance analysis results, candidate correction pathways, and re-evaluation results to the user; and an iterative re-evaluation module 3416 operative on the controller to automatically re-run the relevant compliance analyses on the modified design plan representation upon application of a selected correction pathway.

The controller may be embodied as a cloud server, an on-premises server, a network server, or a combination of computing resources distributed across local and remote environments. The user computing device 3420, which may include a workstation, laptop, tablet, or smart device, connects to the controller via a network 3418 to access the interactive user interface. Communication between the user computing device and the controller may occur over any suitable network, including local area networks, wide area networks, and the internet. In some embodiments, portions of the processing described herein, including AI engine inference and generative model querying, may be performed on specialized AI processing hardware, including dedicated neural network accelerator chips, GPU arrays, or other AI-optimized processing architectures.

The compliance rules database may be maintained and updated through direct integration with building code repositories, application programming interfaces provided by regulatory authorities, or periodic manual review and update processes. In preferred embodiments, the compliance rules database includes rules tagged by jurisdiction, code edition, code section identifier, and compliance category, enabling the system to retrieve applicable rules for any combination of geographic location, building type, and code category relevant to a design under review. The compliance rules database may also be updated based on feedback received from authorities having jurisdiction reviewing compliance submissions generated by the system, enabling the system to refine its understanding of how specific code provisions are applied and interpreted in practice.

The AI engine employed for compliance analysis may be based on a deep learning artificial neural network framework and may incorporate image segmentation, object detection, spatial reasoning, and multi-code compliance inference capabilities. The AI engine may be trained on a dataset including large numbers of building design plans spanning diverse building types, jurisdictions, and compliance domains, together with verified compliance assessments associated with each training example. The AI engine may be retrained or fine-tuned on a continuous basis using new design plan data processed by the system, enabling the AI engine to improve its compliance analysis accuracy and adapt to evolving code requirements and design practices over time.

The following examples illustrate the operation of the present invention in specific compliance failure scenarios. These examples are provided for purposes of illustration and are not limiting of the scope of the invention.

In a first exemplary embodiment, an architect uploads a commercial building design plan to the system. The AI engine analyzes the design plan and detects a compliance failure with respect to the ADA requirement for wheelchair turning clearance at a specific location within the building—a private office near a restroom corridor. The measured turning clearance at that location is 55 inches by 55 inches, which falls below the ADAAG minimum requirement of 60 inches in diameter for a circular turning space. The failure context construction module assembles a failure context including: a description of the failure including the measured dimension and required dimension; the geometry of the office space including its current boundaries, furniture placement areas, and adjacency to the corridor wall and restroom entrance; identification of adjacent design elements including the corridor wall, a fixed built-in bookcase shown in the design, and the restroom door swing arc; and the applicable code citation ADAAG Section 304.3. The controller submits this failure context to the generative language model. The generative language model generates three candidate correction pathways: a first candidate proposing to widen the office by eighteen inches along the corridor wall, increasing the available turning clearance to the required 60-inch minimum; a second candidate proposing to remove the built-in bookcase from the turning clearance zone, which would expand the available clear floor space to satisfy the turning clearance requirement without structural modification; and a third candidate proposing to reconfigure the office door swing from a swing-in to a swing-out or pocket door arrangement, which would increase the effective clear floor space within the office. These three candidates are presented to the architect in the interactive user interface alongside the design plan, with each candidate displayed as a selectable option. The architect selects the second candidate—removal of the built-in bookcase from the turning clearance zone. The controller applies this modification to the dynamic design plan representation and automatically re-runs the wheelchair turning clearance compliance analysis. The re-evaluation confirms that the available turning clearance with the bookcase removed satisfies the 60-inch minimum requirement and that no new compliance failures have been introduced. The compliance status for this location is updated to compliant, and the architect proceeds to the next identified issue.

In a second exemplary embodiment, an architect uploads a multi-tenant commercial building design plan to the system. The AI engine analyzes the design plan and detects multiple compliance failures including a failure with respect to IBC requirements for minimum plumbing fixture counts based on the determined occupancy load for the building. The failure context for this failure includes: the building occupancy classification determined by the AI engine; the calculated occupancy load for the building; the plumbing fixture counts for each fixture type as identified in the design plan; and the minimum fixture counts required by the applicable plumbing code for the determined occupancy and building use. The generative language model generates candidate correction pathways including: a first candidate identifying specific locations within the building floor plan where additional water closets could be added based on available floor area and proximity to existing plumbing rough-in locations; a second candidate proposing a modification to the occupancy classification of a portion of the building that would reduce the calculated occupancy load and bring the existing fixture count into compliance; and a third candidate proposing reconfiguration of a storage room into a restroom facility to add the required fixtures. The architect reviews the three candidates and selects the first candidate for further review. Upon applying the selected correction to the design plan representation, the iterative re-evaluation confirms that the added fixtures bring the building into compliance with the applicable plumbing fixture count requirements and that no new failures are introduced. The re-evaluation results are presented to the architect in the interactive user interface.

In a third exemplary embodiment, a design team uploads a multi-story building design plan that is subject to NFPA 101 smoke control requirements. The AI engine identifies a compliance failure with respect to required smoke compartmentation for a floor with an open atrium configuration. The failure context includes the geometry of the atrium space, the floor area on each side of the atrium, the current compartmentation elements as identified in the design plan, and the NFPA 101 requirements for smoke compartmentation area and construction. The generative language model generates candidate correction pathways including: a first candidate proposing the addition of smoke barriers at specified locations with identified construction specifications; a second candidate proposing mechanical smoke control measures including atrium exhaust and pressurization of adjacent floor areas with preliminary system capacity specifications; and a third candidate proposing a redesign of the atrium configuration to reduce the affected floor area on each side below the threshold that requires the more stringent compartmentation measures. The design team selects the second candidate involving mechanical smoke control and the controller applies the relevant modifications to the design plan representation. The iterative re-evaluation confirms that the specified mechanical smoke control measures, as represented in the modified design plan, satisfy the NFPA 101 requirements for the atrium configuration and that no new compliance failures are introduced.

In a fourth exemplary embodiment illustrating the autonomous plan geometry regeneration capability, an architect is reviewing a water closet design plan, and the AI engine identifies a compliance failure with respect to ADA requirements for the clear floor space at the side of a water closet. The measured clear floor space is insufficient due to the proximity of a lavatory fixture. The failure context is submitted to a generative language model configured for autonomous plan geometry regeneration. The generative language model generates three candidate correction pathways including geometric parameters: a first candidate specifying the new position coordinates for the lavatory fixture to achieve the required clear floor space; a second candidate specifying new wall boundary coordinates that would widen the water closet compartment to achieve the required clearance; and a third candidate specifying the removal of the lavatory from the water closet compartment and its relocation to an adjacent hand-washing area. Each candidate is presented to the architect in the interactive user interface with a preview rendering showing the modified design. The architect selects the first candidate. The controller parses the geometric parameters from the selected correction pathway and applies them directly to the dynamic design plan representation, repositioning the lavatory fixture to the specified coordinates without requiring the architect to manually modify the design in a separate CAD tool. The iterative compliance re-evaluation confirms that the repositioned lavatory provides the required clear floor space and that no new compliance failures result. The architect views the modified design in the interactive user interface and, if satisfied, may proceed to export the updated design plan for further review or submission.

In some embodiments, the system maintains a database of compliance failure conditions, applied correction pathways, and iterative re-evaluation outcomes derived from design plans processed by the system over time. This database serves multiple purposes. First, the database may be used to provide analogical context in the failure context submitted to the generative language model, enabling the model to draw on examples of similar failure conditions and effective correction approaches encountered in previously processed design plans. Second, the database may be used to retrain or fine-tune the generative language model on domain-specific correction pathway data, improving the relevance and accuracy of correction candidates generated for building design plan compliance failures over time. Third, the database may be analyzed to identify patterns in common compliance failure conditions across building types, jurisdictions, and code domains, providing insights useful for improving the underlying compliance analysis capabilities of the system and for identifying areas where building design education and code guidance may benefit practitioners.

The database of compliance analyses and correction outcomes may also be used to support a prioritization capability within the correction pathway generation pipeline. When the AI engine detects multiple compliance failure conditions in a design plan, the system may prioritize the order in which failure contexts are presented to the user for correction based on factors such as the severity of the failure, the impact of the failure on building safety or occupant welfare, the complexity of the available corrections, or the dependencies among failure conditions where resolution of one failure may affect the resolution of another. The prioritization may be automated, user-configurable, or both.

The interactive user interface of the present invention supports a user workflow that integrates seamlessly with existing building design and compliance review practices. A user-- which may include an architect, engineer, building designer, compliance reviewer, building official, or other interested party-- uploads a design plan to the system and initiates a compliance analysis. The system performs the AI-based compliance analysis and presents the results in the interactive user interface, with visual indicators on the design plan highlighting the locations and nature of detected compliance failure conditions.

For each detected compliance failure condition, the user may initiate the correction pathway generation pipeline by selecting the failure indicator in the interactive user interface. The system presents the candidate correction pathways for the selected failure in a correction options panel, and the user reviews and selects a candidate for application. The system applies the selected correction to the dynamic design plan representation and re-evaluates compliance, reporting the results in the interactive user interface. The user may accept the correction as applied, request additional correction options, modify the applied correction through direct interaction with the dynamic design plan components, or discard the correction and return to the candidate selection panel.

The interactive user interface may also present a compliance summary dashboard that shows the overall compliance status of the design plan across all applicable code categories, the number and severity of remaining unresolved compliance failures, the corrections applied to date and their verification status, and the overall progress of the compliance resolution workflow. This dashboard enables the user to efficiently manage a multi-failure compliance review process and track progress toward a fully compliant design.

In some embodiments, the system supports a collaborative compliance review workflow in which multiple users—for example, an architect, a structural engineer, and a fire protection engineer—may access the interactive user interface simultaneously and participate in the compliance analysis and correction selection process. The system may track contributions and corrections by user, maintain a version history of the design plan and compliance status, and generate a compliance audit trail documenting the analysis, corrections applied, and verification results for the entire review process.

In some embodiments, the correction pathway generation pipeline is integrated with a construction cost estimation capability. For each candidate correction pathway generated by the generative language model, the system may generate a preliminary cost estimate for implementing the proposed modification, based upon AI determination of the architectural elements affected by the correction, applicable material costs, labor rates for the geographic location of the building, and other estimation factors. The cost estimates for the candidate correction pathways may be presented alongside the correction descriptions in the candidate presentation panel, enabling the user to evaluate the relative financial implications of different correction approaches in addition to their design merits. The cost estimation capability may draw upon the estimation automation capabilities disclosed in the parent applications, including AI-based determination of material quantities, cost databases, and regional labor rate factors.

The AI engine and generative language model of the present invention may be trained and improved on an ongoing basis using data generated by the operation of the system. Training data may include design plans analyzed by the system, the compliance failure conditions identified in those analyses, the candidate correction pathways generated by the generative language model, the corrections selected by users, the results of iterative compliance re-evaluations following correction application, and, in embodiments where the system receives feedback from authorities having jurisdiction, the outcomes of formal compliance reviews and permitting decisions. By accumulating this operational data over time and using it to retrain or fine-tune the AI engine and generative language model, the system may improve the accuracy of its compliance analysis, the relevance and quality of its correction pathway generation, and its ability to predict and address compliance failure conditions proactively as design plans are being developed.

In some embodiments, user corrections to AI engine outputs—such as a user modifying a boundary predicted by the AI engine or adjusting a component parameter identified incorrectly by the AI engine—are captured and incorporated into the training dataset for the AI engine. This user-feedback-driven training loop enables the AI engine to learn from the domain expertise of the professional users of the system and improve its feature recognition and compliance analysis capabilities on a continuous basis.

The controller of the present invention may be implemented using any suitable computing hardware and software architecture. In preferred embodiments, the controller includes one or more server-grade processors in communication with a storage device, a network interface, and an AI processing unit. The AI processing unit may include one or more of: a general-purpose graphics processing unit configured for neural network inference; a dedicated neural network accelerator chip; a tensor processing unit; or other AI-optimized processing hardware. The storage device may include combinations of magnetic storage, solid-state storage, and memory devices providing sufficient capacity to store the compliance rules database, AI model parameters, design plan data, and correction pathway databases maintained by the system.

The user computing device may include a workstation, laptop, tablet, or smart device capable of presenting the interactive user interface and communicating with the controller over a network connection. In some embodiments, a mobile device application may be provided that enables a user to upload a design plan photograph or file captured on the mobile device, initiate a compliance analysis, and review correction pathway options from the mobile device interface. A directional sensor, LiDAR sensing system, and optical capture device of the type described in the parent applications may be incorporated into the mobile device to capture design plan data from physical drawings.

The present invention may be implemented as a software-as-a-service platform accessible via a web browser, as a locally installed desktop application, as a cloud-hosted platform, or as any combination of these deployment modalities. An application programming interface may be provided to enable integration of the correction pathway generation and iterative re-evaluation capabilities of the present invention with third-party building design software, CAD tools, BIM platforms, and permitting authority systems.

1. A system comprising:
a controller comprising one or more processors and a storage device;
an artificial intelligence engine operative on the controller;
a compliance rules database accessible to the controller, the compliance rules database storing a requirement set associated with an authority having jurisdiction;
a generative language model accessible to the controller; and
an interactive user interface module operative on the controller,
wherein the controller is configured to receive a digital design plan of at least a portion of a building, analyze the digital design plan using the artificial intelligence engine to ascertain at least one design parameter represented by the digital design plan, compare the at least one design parameter against the requirement set, detect at least one condition of the digital design plan that does not comply with the requirement set, construct a failure context comprising data descriptive of the at least one condition, plan geometry associated with the at least one condition, and at least one requirement of the requirement set implicated by the at least one condition, submit the failure context to the generative language model, receive from the generative language model at least one candidate correction pathway describing a change to the digital design plan calculated to bring the digital design plan into compliance with the at least one requirement, and present the at least one candidate correction pathway through the interactive user interface module.

2. The system of claim 1, wherein the controller is configured to select the requirement set based on a geographic location associated with the building.

3. The system of claim 1, wherein the artificial intelligence engine is configured to identify architectural elements represented by the digital design plan and to derive the at least one design parameter from the identified architectural elements.

4. The system of claim 1, wherein the failure context further comprises a measured value for the at least one design parameter and a required value or threshold specified by the at least one requirement.

5. The system of claim 1, wherein the failure context further comprises data identifying a neighboring design element that constrains or affects the change described by the at least one candidate correction pathway.

6. The system of claim 1, wherein the controller is configured to receive from the generative language model a plurality of candidate correction pathways that represent different alternative changes to the digital design plan.

7. The system of claim 6, wherein the interactive user interface module is configured to present the plurality of candidate correction pathways as candidate options subject to user evaluation and system verification rather than as certified compliant design solutions.

8. The system of claim 1, wherein the controller is configured to receive a user selection of the at least one candidate correction pathway, apply the change described by the selected at least one candidate correction pathway to a dynamic design plan representation, and automatically re-run a compliance analysis on the dynamic design plan representation after application of the change.

9. The system of claim 8, wherein the controller is configured to determine, based on the compliance analysis re-run after the application of the change, whether the selected candidate correction pathway resolves the at least one condition without introducing a new condition that does not comply with the requirement set.

10. The system of claim 1, wherein the at least one candidate correction pathway comprises geometric parameters directly applicable by the controller to modify a dynamic design plan representation.

11. A system comprising:
a controller comprising one or more processors and a storage device;
an artificial intelligence engine operative on the controller;
a fire code rules database accessible to the controller, the fire code rules database storing a fire code requirement adopted or enforced by an authority having jurisdiction;
a generative language model accessible to the controller; and
an interactive user interface module operative on the controller,
wherein the controller is configured to receive a digital design plan of at least a portion of a building, analyze the digital design plan using the artificial intelligence engine to ascertain at least one fire-protection parameter represented by the digital design plan, compare the at least one fire-protection parameter against the fire code requirement, detect at least one condition of the digital design plan that does not comply with the fire code requirement, construct a failure context comprising data descriptive of the at least one condition, plan geometry associated with the at least one condition, and the fire code requirement implicated by the at least one condition, submit the failure context to the generative language model, receive from the generative language model at least one candidate correction pathway describing a change to the digital design plan calculated to bring the digital design plan into compliance with the fire code requirement, and present the at least one candidate correction pathway through the interactive user interface module.

12. The system of claim 11, wherein the controller is configured to select the fire code requirement based on a geographic location associated with the building.

13. The system of claim 11, wherein the fire code requirement comprises a requirement from a National Fire Protection Association code, an International Fire Code, an International Building Code, or a local fire code adopted by the authority having jurisdiction.

14. The system of claim 11, wherein the at least one fire-protection parameter comprises an occupant load, an egress capacity, an egress width, a travel distance, a common path of travel, a dead-end corridor length, an exit separation distance, or a door swing direction.

15. The system of claim 11, wherein the at least one fire-protection parameter comprises a sprinkler spacing, a sprinkler coverage area, a sprinkler obstruction condition, a hazard classification, a detector spacing, a notification appliance coverage, a fire barrier continuity condition, a fire door rating, a smoke control parameter, a fire extinguisher travel distance, or a standpipe hose reach parameter.

16. The system of claim 11, wherein the failure context comprises a measured value for the at least one fire-protection parameter and a required value or threshold specified by the fire code requirement.

17. The system of claim 11, wherein the failure context comprises a dependency annotation identifying at least one additional fire-protection variable expected to be affected by the change described by the at least one candidate correction pathway.

18. The system of claim 11, wherein the controller is configured to receive from the generative language model a plurality of candidate correction pathways representing different alternative changes to the digital design plan and to present the plurality of candidate correction pathways as selectable options through the interactive user interface module.

19. The system of claim 18, wherein the controller is configured to apply a selected candidate correction pathway to a dynamic design plan representation and automatically re-run a fire code compliance analysis on the dynamic design plan representation after application of the selected candidate correction pathway.

20. The system of claim 19, wherein the controller is configured to determine, based on the fire code compliance analysis re-run after the application of the selected candidate correction pathway, whether the selected candidate correction pathway resolves the at least one condition without introducing a new condition that does not comply with the fire code requirement.
